(19) United States
(12) Patent Application Publication
(10) Pub. No.: US 2026/0009821 A1
(43) Pub. Date: Jan. 8, 2026

(54) ELECTRICALLY CONDUCTIVE CONTACT PIN AND METHOD FOR MANUFACTURING SAME

(71) Applicant: POINT ENGINEERING CO., LTD., Chungcheongnam-do (KR)

(72) Inventors: Bum Mo AHN, Gyeonggi-do (KR); Seung Ho PARK, Gyeonggi-do (KR); Sung Hyun BYUN

(73) Assignee: POINT ENGINEERING CO., LTD., Chungcheongnam-do (KR)

(21) Appl. No.: 18/997,184

(22) PCT Filed: Jul. 18, 2023
(86) PCT No.: PCT/KR2023/010281

§ 371 Date: Jan. 21, 2025

(30) Foreign Application Priority Data
Aug. 1, 2022 (KR) 10-2022-0095606
Jul. 18, 2023 (WO) PCT/KR2023/010281

(51) Int. Cl. G01R 1/067; G01R 31/26

(52) U.S. Cl. CPC G01R 1/06738; G01R 1/06716; G01R 1/06761; G01R 31/2601

(57) ABSTRACT

Proposed are an electrically conductive contact pin and a method for manufacturing the same. The electrically conductive contact pin includes a body portion composed of a plurality of metal layers stacked in a thickness direction, and a tip portion provided on at least one of a front end portion and a base end portion of the body portion, wherein the tip portion has dimensions smaller than the dimensions of the thickness direction of the body portion, and a metal layer constituting the tip portion is formed continuously of the same material as some of the metal layers constituting the body portion.

### CROSS-REFERENCES

This application is a 371 of international application of PCT application serial no. PCT/KR2023/010281, filed on Jul. 18, 2023, which claims the priority benefit of Korea application no. 10-2022-0095606, filed on Aug. 1, 2022. The entirety of each of the above mentioned patent applications is hereby incorporated by reference herein and made a part of this specification.

### TECHNICAL FIELD

The present disclosure relates to an electrically conductive contact pin and a method for manufacturing the same.

### DESCRIPTION OF RELATED ART

Testing the electrical properties of semiconductor devices is performed by approaching an object to be inspected (semiconductor wafer or semiconductor package) to an inspection device equipped with a plurality of electrically conductive contact pins and contacting the electrically conductive contact pins with corresponding electrode pads (or solder balls or bumps) on the object to be inspected.

When the electrically conductive contact pin and the electrode pad on the inspection object are brought into contact, after the two reach a state in which they begin to contact, a process of additionally approaching the inspection object is performed. This process is called overdrive. Overdrive is an operation that elastically deforms electrically conductive contact pins, and by performing overdrive, even if there is a difference in the height of the electrode pads or the height of the electrically conductive contact pins, all electrically conductive contact pins may be reliably contacted with the electrode pads. In addition, during overdrive, the electrically conductive contact pin elastically deforms and the tip thereof moves on the electrode pad, thereby performing scrubbing. This scrubbing removes an oxide film on the surface of the electrode pad and reduces contact resistance.

Electrically conductive contact pins may be manufactured using micro-electro-mechanical systems (MEMS) processing. To explain the process of manufacturing an electrically conductive contact pin using a MEMS process, first, a photoresist film is applied to the surface of a conductive substrate, and then the photoresist film is patterned. Afterwards, using the photoresist film as a mold, a metal material is deposited on the exposed surface of the conductive substrate within an opening by electroplating, and the photoresist film and the conductive substrate are removed to obtain a contact pin. In this way, electrically conductive contact pins manufactured using the MEMS process are hereinafter referred to as MEMS contact pins. A MEMS contact pin has the same shape as that of the opening formed in the mold of the photoresist film.

As such, since the photoresist film of conventional MEMS contact pins is thin, about 30 μm, it is difficult to make a tip portion thinner than a body portion using a single photoresist film. Meanwhile, in order to thin the tip portion of the contact pin to a thickness different from that of the body portion, the process of applying a photoresist film needs to be performed several times. In this case, on the side of the MEMS contact pin, a joint like a bamboo node appears at each layer change, making prone to deformation. Moreover, because the tip portion is made of a separate metal material from the body portion, the continuity of the tip portion as the same material as the metal material of the body portion is reduced, resulting in an increase in electrical resistance.

Therefore, conventional MEMS contact pins have limitations in improving connection reliability.

### DOCUMENT OF RELATED ART

### Patent Document

(Patent Document 1) Korean Patent Application Publication No. 10-2018-0004753

### SUMMARY OF THE INVENTION

### Technical Problem

The present disclosure is intended to solve the above problems occurring in the related art. An objective of the present disclosure is to provide an electrically conductive contact pin with improved connection reliability and a method for manufacturing the same.

In addition, an objective of the present disclosure is to provide an electrically conductive contact pin with improved electrical conductivity by eliminating resistance elements that impede electrical flow, and a method for manufacturing the same.

In addition, an objective of the present disclosure is to provide a method for manufacturing an electrically conductive contact pin to produce a stepped tip portion using a single mold.

### Technical Solution

In order to achieve the above-mentioned objectives, there is provided an electrically conductive contact pin including: a body portion composed of a plurality of metal layers stacked in a thickness direction; and a tip portion provided on at least one of a front-end portion and a base-end portion of the body portion, wherein the tip portion may have dimensions smaller than dimensions of the body portion in the thickness direction, and a metal layer constituting the tip portion may be formed continuously of a same material as some of the metal layers constituting the body portion.

In addition, the tip portion may be composed of a plurality of metal layers stacked in the thickness direction, and may have a stacked number smaller than that of the metal layers constituting the body portion.

In addition, lowermost and uppermost layers of the body portion may be composed of a first metal layer, whereas a lowermost layer of the tip portion may be composed of a second metal layer and an uppermost layer of the tip portion may be composed of the first metal layer.

In addition, a fine trench may be provided on a side of the body portion and a side of the tip portion.

In addition, a slit provided inside the body portion may be included, and the body portion may elastically deform in a width direction.

In addition, the body portion may include an elastic portion provided by bending a plate, and the elastic portion may elastically deform in a length direction.

Meanwhile, according to an embodiment of the present disclosure, there is provided an electrically conductive contact pin including: a first region composed of a plurality of metal layers stacked in a thickness direction; a second region having smaller dimensions than dimensions of the first region in the thickness direction, having a stacked number smaller than that of the metal layers constituting the first region, and comprising a metal layer formed continuously with some of the metal layers constituting the first region; and a third region located between the first region and the second region and connecting metal layers of a same material of the first region and the second region.

In addition, the second region may be a tip portion that contacts an object to be connected.

In addition, the metal layers may include a first metal layer and a second metal layer, wherein the first metal layer may be formed of a metal selected from rhodium (Rd), platinum (Pt), iridium (Ir), palladium (Pd), nickel (Ni), manganese (Mn), tungsten (W), phosphorus (Ph) or alloys thereof, or palladium-cobalt (PdCo) alloy, palladium-nickel (PdNi) alloy, or nickel-phosphorus (NiPh) alloy, nickel-manganese (NiMn), nickel-cobalt (NiCo) or Nickel-tungsten (NiW) alloy, whereas the second metal layer may be formed of a metal selected from copper (Cu), silver (Ag), gold (Au), or alloys thereof.

In addition, the first metal layer may be provided at lowermost and uppermost layers of the first region, whereas the second metal layer may be provided at lowermost layers of the second and third regions, and the first metal layer may be provided at uppermost layers of the second and third regions.

In addition, a metal layer of the third region may include: a first connection portion connected to a metal layer of the first region; a second connection portion connected to a metal layer of the second region; and a middle portion provided between the first connection portion and the second connection portion.

In addition, one of metal layers constituting the third region may be in contact with the plurality of metal layers of the first region.

In addition, the middle portion may be composed of a second metal layer.

Meanwhile, according to an embodiment of the present disclosure, there is provided a method for manufacturing an electrically conductive contact pin, the method including: forming a first internal space by removing a part of a mold; forming a metal layer in a first height section of the first internal space; removing a part of the mold and forming a second internal space in communication with the first internal space; and forming a metal layer in a second height section of the first internal space and in the second internal space.

In addition, in the forming a metal layer in a first height section of the first internal space, metal layers may be alternately plated to form the metal layer.

In addition, in the forming a metal layer in a second height section of the first internal space and in the second internal space, metal layers may be alternately plated to form the metal layer.

In addition, the mold may be a mold made of an anodic oxide material.

### Advantageous Effects

The present disclosure provides an electrically conductive contact pin with improved connection reliability and a method for manufacturing the same.

Furthermore, the present disclosure provides an electrically conductive contact pin with improved electrical conductivity by eliminating resistance elements that impede electrical flow, and a method for manufacturing the same.

Furthermore, the present disclosure provides a method for manufacturing an electrically conductive contact pin to produce a stepped tip portion using a single mold.

### BRIEF DESCRIPTION OF DRAWINGS

FIG. 1 is a plan view of an electrically conductive contact pin according to a first preferred embodiment of the present disclosure.

FIG. 2A is an enlarged view of part A of FIG. 1, and FIG. 2B is a perspective view of FIG. 2A.

FIGS. 3 and 4 are enlarged views of the ends shown in FIGS. 2A and 2B.

FIG. 5A is an enlarged view of part B of FIG. 1, and FIG. 5B is a perspective view of FIG. 5A.

FIG. 6A is an enlarged view of part C of FIG. 1, and FIG. 6B is a perspective view of FIG. 6A.

FIG. 7A is an enlarged view of part D of FIG. 1, and FIG. 7B is a perspective view of FIG. 7A.

FIG. 8 is a view showing an inspection device equipped with an electrically conductive contact pin according to a first preferred embodiment of the present disclosure.

FIGS. 9A to 14B are views showing a method for manufacturing an electrically conductive contact pin according to a first preferred embodiment of the present disclosure.

FIG. 15 is an enlarged perspective view of part B of FIG. 14B.

FIG. 16 is a plan view of an electrically conductive contact pin according to a second preferred embodiment of the present disclosure.

FIG. 17 is an enlarged view of part A of FIG. 16.

FIG. 18 is an enlarged view of part B of FIG. 16.

FIG. 19 is an enlarged view of part C of FIG. 16.

FIG. 20 is a partially enlarged perspective view of FIG. 19.

FIG. 21 is a view showing an inspection device equipped with an electrically conductive contact pin according to a second preferred embodiment of the present disclosure.

### DESCRIPTION OF THE INVENTION

The following merely illustrates the principles of the disclosure. Therefore, those skilled in the art will be able to invent various devices that embody the principles of the invention and are included in the concept and scope of the invention, although not explicitly described or shown herein. In addition, all conditional terms and embodiments listed in this specification are, in principle, expressly intended only for the purpose of ensuring that the inventive concept is understood, and should be understood as not limiting to the embodiments and conditions specifically listed as such.

The above-mentioned purpose, features and advantages will become clearer through the following detailed description in conjunction with the accompanying drawings, and accordingly, those skilled in the art in the technical field to which the present disclosure pertains will be able to easily implement the technical idea of the present disclosure.

The embodiments described herein will be explained with reference to cross-sectional views and/or perspective views, which are ideal illustrations of the present disclosure. The thicknesses of films and regions shown in these drawings are exaggerated for effective explanation of technical content. The form of the illustration may be modified depending on manufacturing technology and/or tolerance. In addition, the number of molded products shown in the drawings is only a partial number shown in the drawings as an example. Accordingly, the embodiments of the present disclosure are not limited to the specific form shown, but also include changes in form produced according to the manufacturing process.

In describing various embodiments, components that perform the same function will be given the same names and the same reference numbers for convenience even if the embodiments are different. Furthermore, for convenience, the description of the configuration and operation already described in other embodiments will be omitted.

Electrically conductive contact pins 100 and 200 according to a preferred embodiment of the present disclosure are provided in inspection devices 10 and 20 and are used to transmit electrical signals by electrically and physically contacting an inspection object. The inspection devices 10 and 20 include electrically conductive contact pins 100 and 200 that contact the inspection object. The inspection device may be testing equipment used in a semiconductor manufacturing process, and for example, the inspection device may be a probe card or a test socket. The inspection device according to the preferred embodiment of the present disclosure is not limited thereto, and includes any device for checking whether an inspection object is defective by applying electricity.

The electrically conductive contact pins 100 and 200 according to a preferred embodiment of the present disclosure may be electrically conductive contact pins 100 and 200 capable of transmitting signals having a frequency greater than 1 GHz, and the total length of the electrically conductive contact pin 100 or 200 may be 10 mm or less.

The width direction of the electrically conductive contact pins 100 and 200 described below is the ±x direction indicated in the drawings, the length direction of the electrically conductive contact pins 100 and 200 is the ±y direction indicated in the drawings, and the thickness direction of the electrically conductive contact pins 100 and 200 is the ±z direction indicated in the drawings. The electrically conductive contact pin 100 or 200 has an overall length dimension L in the length direction (±y direction), an overall thickness dimension H in the thickness direction perpendicular to the length direction (±z direction), and an overall width dimension W in the width direction perpendicular to the length direction (±x direction).

### First Embodiment

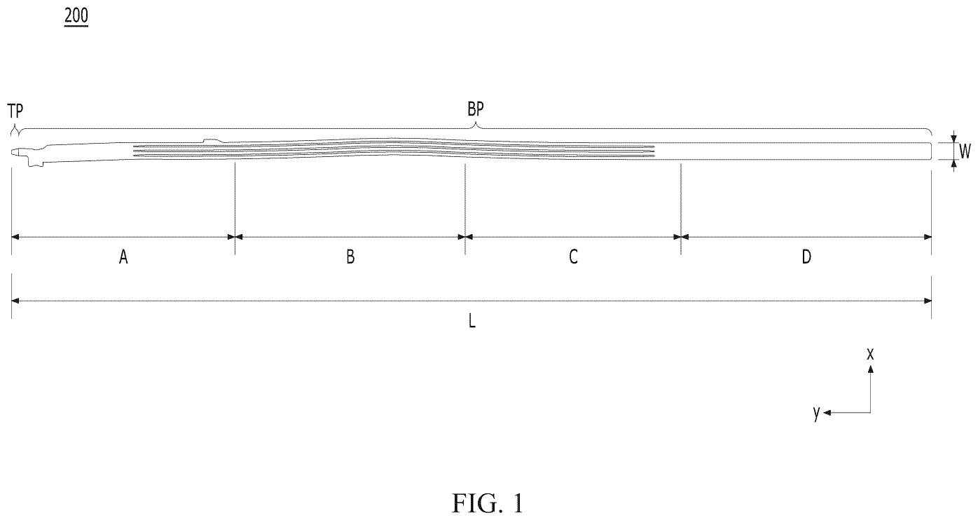

Hereinafter, the electrically conductive contact pin 200 according to a first preferred embodiment of the present disclosure and a method for manufacturing the same will be described with reference to FIGS. 1 to 15.

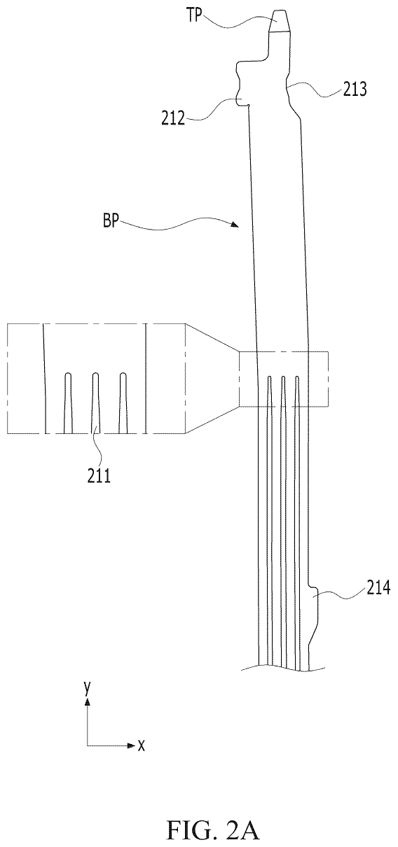

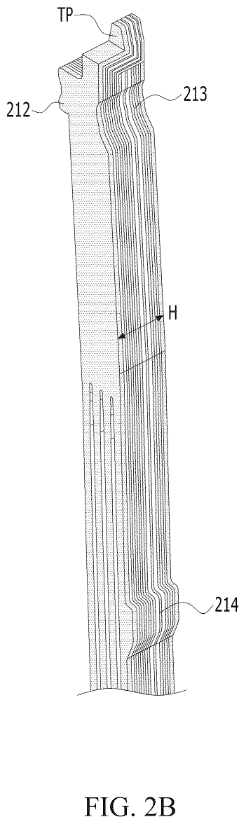

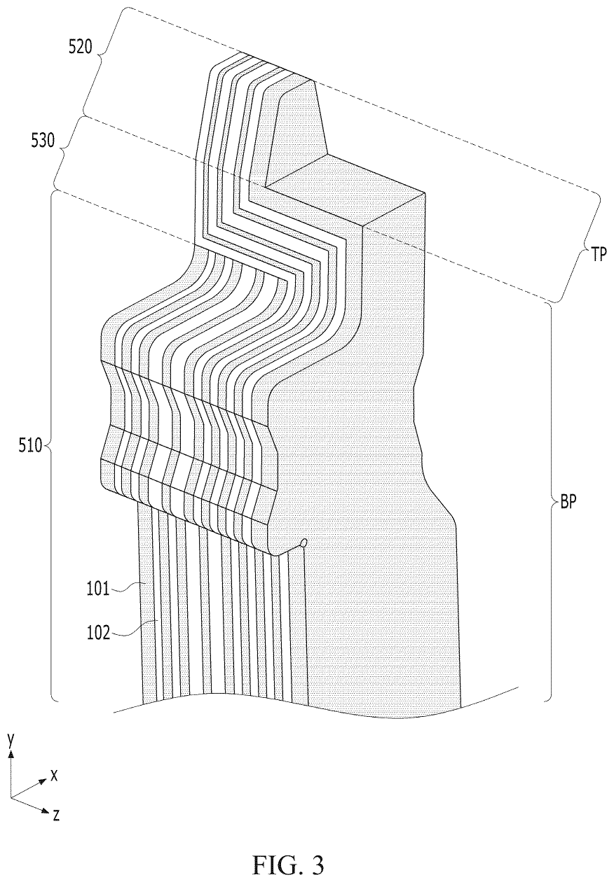

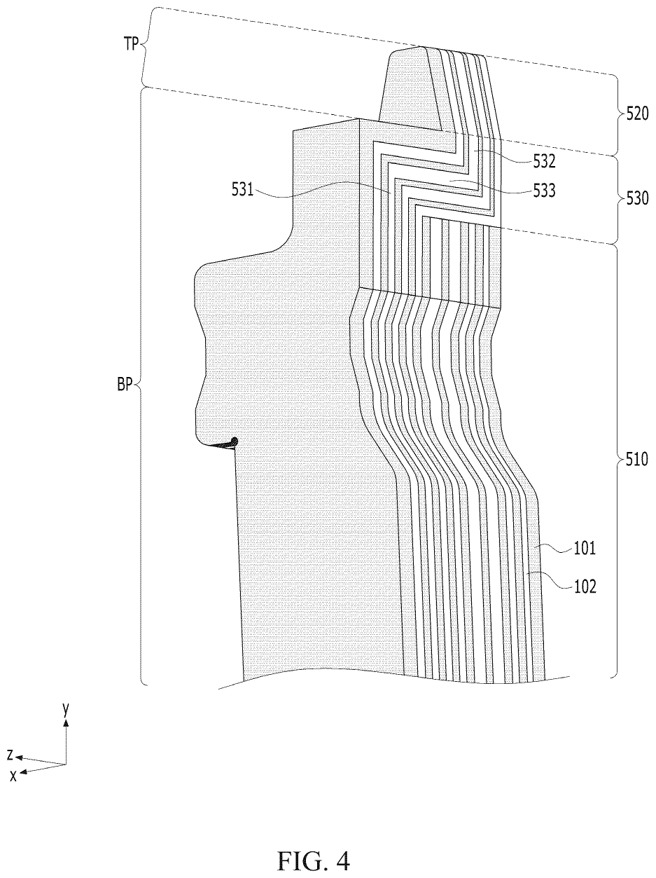

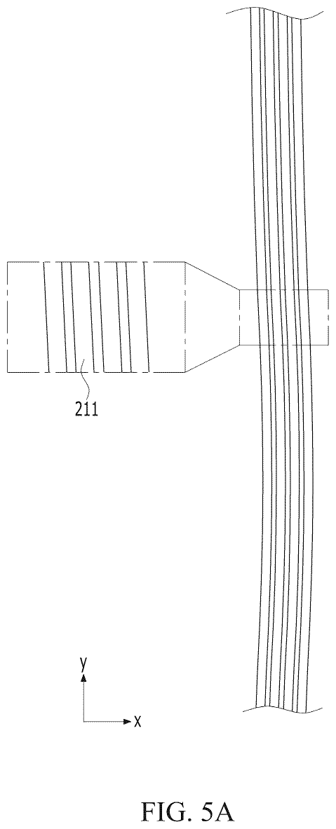

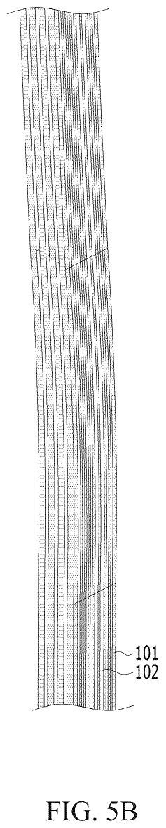

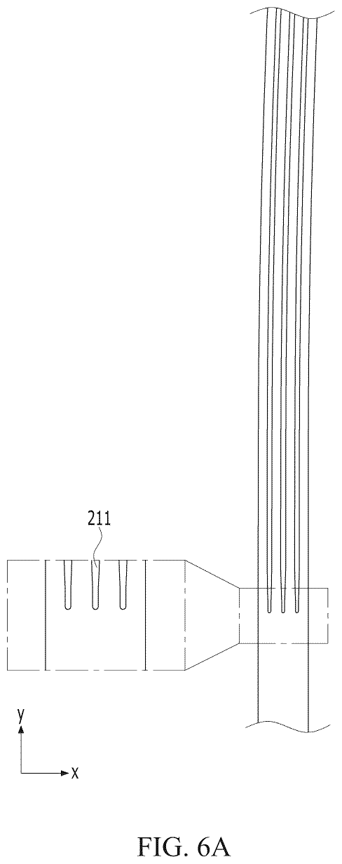

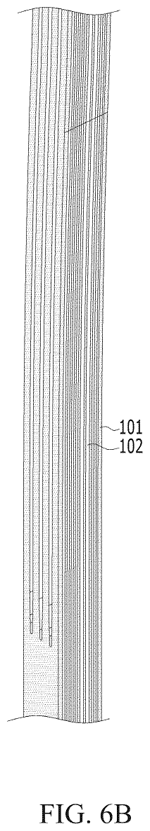

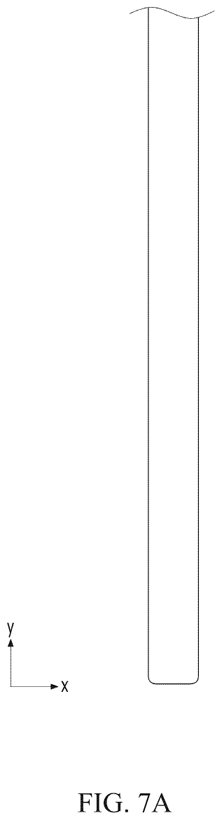

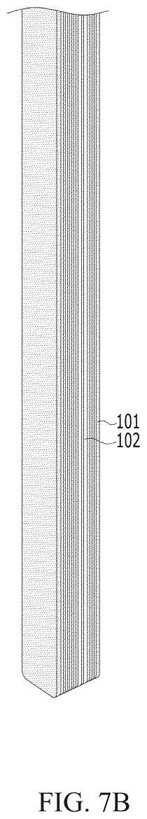

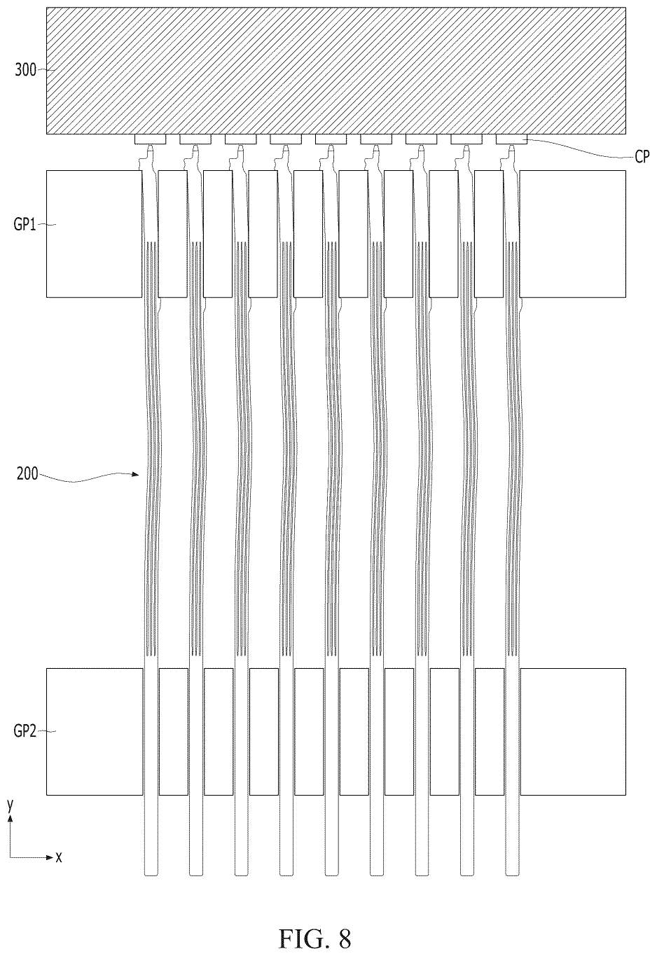

FIG. 1 is a plan view of the electrically conductive contact pin 200 according to the first preferred embodiment of the present disclosure; FIG. 2A is an enlarged view of part A of FIG. 1, and FIG. 2B is a perspective view of FIG. 2A; FIGS. 3 and 4 are enlarged views of the ends shown in FIGS. 2A and 2B; FIG. 5A is an enlarged view of part B of FIG. 1, and FIG. 5B is a perspective view of FIG. 5A; FIG. 6A is an enlarged view of part C of FIG. 1, and FIG. 6B is a perspective view of FIG. 6A; FIG. 7A is an enlarged view of part D of FIG. 1, and FIG. 7B is a perspective view of FIG. 7A; and FIG. 8 is a view showing the inspection device 20 equipped with the electrically conductive contact pin 200 according to the first preferred embodiment of the present disclosure.

The electrically conductive contact pin 200 has a first surface (upper surface in the +z direction), a second surface opposite the first surface (lower surface in the +z direction), and a side surface connecting the first surface and the second surface. The tip of the electrically conductive contact pin 200 is connected to a circuit board, and the lower end of the electrically conductive contact pin 200 is connected to an inspection object. In this case, the inspection object may be a semiconductor wafer.

The electrically conductive contact pin 200 is a probe disposed perpendicular to the inspection object and includes a body portion BP that elastically deforms in the width direction (±x direction) during an overdrive process.

The body portion BP is formed to be long in the length direction (±y direction). The cross section of the body portion BP is formed as a square cross section. In this case, guide holes of an upper guide plate GP1 and a lower guide plate GP2 may be provided with a square cross-section to correspond to the cross-sectional shape of the body portion BP. Due to the configuration of the body portion BP with a square cross-section and the guide holes with a square cross-section, the electrically conductive contact pin 200 is prevented from rotating within the guide holes and the elastic deformation direction of the body portion BP is maintained in a certain direction, thereby preventing interference between the contact pins 200 and realizing a narrow pitch.

The body portion BP includes a slit 211 provided in the form of an empty space inside the body portion BP through the first and second surfaces. The slit 211 is formed long along the length direction (±y direction) of the body portion BP. At least one slit 211 may be provided, and three slits 211 are shown in the drawing. By including the slit 211 formed inside the body portion BP, the overall length may be shortened while securing the desired amount of overdrive and securing the desired tracking pressure or allowable time-current characteristics. Since the overall length of the electrically conductive contact pin 200 can be shortened, the inductance of the electrically conductive contact pin 200 may be reduced and the high-frequency characteristics may be improved.

In addition, the slit 211 is provided with an internal width that becomes smaller from the center to the end. For this reason, a beam portion provided on each side of the slit 211 has a root portion that increases in width from the center to the ends, which has the effect of resolving stress concentration occurring at both ends of the slit 211.

The body portion BP is provided with a plurality of metal layers stacked in the thickness direction (±z direction). The plurality of metal layers are metal layers of different materials. The plurality of metal layers includes a first metal layer 101 and a second metal layer 102. The first metal layer 101 is a metal with relatively high rigidity or wear resistance compared to the second metal layer 102, and is preferably made of a metal selected from rhodium (Rd), platinum (Pt), iridium (Ir), palladium (Pd), nickel (Ni), manganese (Mn), tungsten (W), phosphorus (Ph) or alloys thereof, or palladium-cobalt (PdCo) alloy, palladium-nickel (PdNi) alloy, or nickel-phosphorus (NiPh) alloy, nickel-manganese (NiMn), nickel-cobalt (NiCo) or Nickel-tungsten (NiW) alloy. The second metal layer 102 is a metal with relatively high electrical conductivity compared to the first metal layer 101, and is preferably formed of a metal selected from copper (Cu), silver (Ag), gold (Au), or alloys thereof.

The first metal layer 101 is provided on the lower and upper surfaces of the body portion BP in the thickness direction (±z direction), and the second metal layer 102 is provided between the first metal layers 101. For example, the body portion BP is provided by alternately stacking the first metal layer 101, the second metal layer 102, and the first metal layer 101 in that order, and the number of stacked layers may be three or more. The drawing shows that 17 metal layers are stacked. For example, the body portion BP may be composed of alternately stacked palladium-cobalt (PdCo) alloy first metal layer 101—gold (Au) second metal layer 102—palladium-cobalt (PdCo) alloy first metal layer 101 in that order, or composed of alternately stacked palladium-cobalt (PdCo) alloy first metal layer 101—gold (Au) second metal layer 102—nickel-cobalt (NiCo) alloy first metal layer 101—copper (Cu) second metal layer 102 in that order.

The lowermost layer of the body portion BP is the first layer in the thickness direction (±z direction) and the uppermost layer of the body portion BP is the top layer in the thickness direction (±z direction), whereas the lowermost layer of the tip portion TP is the first layer in the thickness direction (±z direction) and the uppermost layer of the tip portion TP is the top layer in the thickness direction (±z direction).

The tip of the body portion BP is on the circuit board 300 side, and the lower end of the body portion BP is the inspection object side. The tip portion TP is provided on at least one of the front-end portion and the base-end portion of the body portion BP. Referring to the drawings, the tip portion TP is provided at the front-end portion of the body portion BP. The present disclosure is not limited to this, and the tip portion TP may be provided at the base-end portion of the body portion BP.

The tip portion TP has smaller dimensions than the dimensions of the body portion BP in the width direction (±x direction).

The tip portion TP has smaller dimensions than the dimensions of the body portion BP in the thickness direction (±z direction), and is provided in a stepped form from the body portion BP. The lower surface of the tip portion TP is located on the same plane as the lower surface of the body portion BP, and the upper surface of the tip portion TP is located at a lower height than the upper surface of the body portion BP. In this case, the lower surface of the tip portion TP is the bottom layer in the thickness direction (±z direction) and the upper surface of the tip portion TP is the top layer in the thickness direction (±z direction).

The tip portion TP has a stacked number smaller than the number of metal layers constituting the body portion BP. To be specific, the tip portion TP is composed of at least one metal layer. For example, the drawing shows eight metal layers being stacked. However, the number of metal layers constituting the tip portion TP is not limited to this, and may be one or more layers, but the number is smaller than the number of metal layers constituting the body portion BP. When the tip portion TP is composed of a plurality of metal layers, the tip portion TP includes the first metal layer 101 and the second metal layer 102, and the first metal layer 101 and the second metal layer 102 are alternately stacked.

The metal layers constituting the tip portion TP are formed continuously of the same material as some of the metal layers constituting the body portion BP. For example, the first layer (lowermost layer) in the thickness direction (±z direction) of the tip portion TP is continuously formed of the same material as the tenth layer in the thickness direction (±z direction) of the body portion BP, the second layer in the thickness direction (±z direction) of the tip portion TP is continuously formed of the same material as the 11th layer in the thickness direction (±z direction) of the body portion BP, the third layer in the thickness direction (±z direction) of the tip portion TP is continuously formed of the same material as the 12th layer in the thickness direction (±z direction) of the body portion BP, the fourth layer in the thickness direction (±z direction) of the tip portion TP is continuously formed of the same material as the 13th layer in the thickness direction (±z direction) of the body portion BP, the fifth layer in the thickness direction (±z direction) of the tip portion TP is continuously formed of the same material as the 14th layer in the thickness direction (±z direction) of the body portion BP, the sixth layer in the thickness direction (±z direction) of the tip portion TP is continuously formed of the same material as the 15th layer in the thickness direction (±z direction) of the body portion BP, the seventh layer in the thickness direction (±z direction) of the tip portion TP is continuously formed of the same material as the 16th layer in the thickness direction (±z direction) of the body portion BP, and the eighth layer in the thickness direction (±z direction) of the tip portion TP is continuously formed of the same material as the 17th layer in the thickness direction (±z direction) of the body portion BP.

The uppermost layer of the tip portion TP is formed continuously of the same material as the uppermost layer of the body portion BP, and the lowermost layer of the tip portion TP is formed continuously of the same material as one of the internal metal layers of the body portion BP. In addition, the metal layer between the lowermost layer of the tip portion TP and the uppermost layer of the tip portion TP is continuously formed of the same material as the inner metal layer of the body portion BP.

In a structure where the tip portion TP and the body portion BP are discontinuously formed from different materials, problems arise where electrical resistance increases at discontinuous boundaries. However, in a configuration in which metal layers of the same material are continuously formed in the tip portion TP and the body portion BP as in the preferred embodiment of the present disclosure, since the flow of electricity from the tip portion TP to the body portion BP is continuous, the problem of increased electrical resistance at the discontinuous boundary as in the conventional case does not occur. In addition, since the metal layers constituting the tip portion TP and the body portion BP are made of the same metal material and are continuous, the problem of the tip portion TP being separated from the body portion BP may be minimized.

The material of the first metal layer 101 corresponding to the 1st, 3rd, 5th, 7th, and 9th layers of the body portion BP and the material of the first metal layer 101 corresponding to the 11th, 13th, 15th, and 17th layers of the body portion BP may be a metal of the same material or a metal of a different material among the metals included in the first metal layer 101. In addition, the material of the second metal layer 102 corresponding to the 2nd, 4th, 6th, and 8th layers of the body portion BP and the material of the second metal layer 102 corresponding to the 10th, 12th, 14th, and 16th layers of the body portion BP may be a metal of the same material or a metal of a different material among the metals included in the second metal layer 102.

Considering the wear resistance of the body portion BP, the lowermost and uppermost layers of the body portion BP may be composed of the first metal layer 101.

The lowermost layer of the tip portion TP may be composed of the second metal layer 102 and the uppermost layer of the tip portion TP may be composed of the first metal layer 101. In this case, the tip portion TP is composed of a plurality of metal layers, including a first metal layer 101 and a second metal layer 102, stacked in the thickness direction (±z direction). In a configuration in which the tip portion TP includes different first and second metal layers 101 and 102, electrical conductivity at the tip portion TP may be improved compared to the case where the tip portion TP consists only of the first metal layer 101, and the rigidity and wear resistance of the tip portion TP may be improved compared to the case where the tip portion TP consists only of the second metal layer 102.

Meanwhile, the lowermost and uppermost layers of the tip portion TP may be composed of the second metal layer 102. In this case, the first metal layer 101 may be provided between the lowermost and uppermost layers of the tip portion TP. In a configuration in which the tip portion TP includes different first and second metal layers 101 and 102, electrical conductivity at the tip portion TP may be improved compared to the case where the tip portion TP consists only of the first metal layer 101, and the rigidity of the tip portion TP may be improved compared to the case where the tip portion TP consists only of the second metal layer 102.

Meanwhile, the lowermost and uppermost layers of the tip portion TP may be composed of the first metal layer 101. In this case, the second metal layer 102 may be provided between the lowermost and uppermost layers of the tip portion TP. In a configuration in which the tip portion TP includes different first and second metal layers 101 and 102, electrical conductivity at the tip portion TP may be improved compared to the case where the tip portion TP consists only of the first metal layer 101, and the rigidity and wear resistance of the tip portion TP may be improved compared to the case where the tip portion TP consists only of the second metal layer 102.

Meanwhile, the tip portion TP may be provided as a single metal layer. The single metal layer may be the first metal layer 101 or the second metal layer 102. In this case as well, the single metal layer constituting the tip portion TP is continuously formed of the same material as the metal layer constituting the body portion BP.

For example, the first metal layer 101 constituting the tip portion TP and the body portion BP may be a palladium-cobalt (PdCo) alloy, and the second metal layer 102 may be gold (Au). All of the second metal layers 102 made of gold (Au) constituting the body portion BP are connected to the second metal layer 102 made of gold (Au) constituting the tip portion TP. Because all of the second metal layers 102 constituting the body portion BP are integrally connected to the second metal layer 102 constituting the tip portion TP, electricity flows continuously from the body portion BP to the tip portion TP or from the tip portion TP to the body portion BP in the second metal layer 102. As a result, the electrical conductivity of the electrically conductive contact pin 200 may be greatly improved. Conventionally, the materials of the tip portion TP and the body portion BP are different, causing resistance to electric flow at the discontinuous boundary. In contrast, according to the present disclosure in which all of the second metal layers 102 of the tip portion TP are integrally connected to all of the second metal layers 102 of the body portion BP, by eliminating resistance elements that impede electrical flow, improved electrical conductivity may be provided.

In addition, for example, the first metal layer 101 constituting the tip portion TP and the body portion BP may be a palladium-cobalt (PdCo) alloy, and the second metal layer 102 may be copper (Cu). In this case, in order to improve the electrical conductivity of the electrically conductive contact pin 200, the surface of the tip portion TP may be additionally coated with gold (Au).

In addition, for example, both the lowermost and uppermost layers of the tip portion TP may be composed of the first metal layer 101. In this case as well, the lowermost and uppermost metal layers of the tip portion TP are formed continuously of the same material as the metal layer of the body portion BP. When both the lowermost and uppermost layers of the tip portion TP are composed of the first metal layer 101, the wear resistance of the tip portion TP may be improved. In addition, when both the lowermost and uppermost layers of the tip portion TP are composed of the first metal layer 101, the second metal layer 102 is provided between the lowermost layer and the uppermost layer to improve the electrical conductivity of the tip portion TP.

In addition, for example, the tip portion TP may be composed of a single layer of the first metal layer 101. In this case as well, the first metal layer 101 of the tip portion TP is formed continuously with the first metal layer 101 of the body portion BP.

In addition, for example, the tip portion TP may be composed of a single layer of the second metal layer 102. In this case as well, the second metal layer 102 of the tip portion TP is formed continuously with the second metal layer 102 of the body portion BP.

The electrically conductive contact pin 200 is divided into a first region 510, a second region 520, and a third region 530 according to the multilayer structure of the metal layers.

The first region 510 is a region composed of a plurality of metal layers stacked in the thickness direction (±z direction). The second region 520 is a region that has smaller dimensions than the dimensions of the first region 510 in the thickness direction (±z direction) and a smaller number of metal layers than the number of metal layers constituting the first region 510. The third region 530 is located between the first region 510 and the second region 520 and connects the metal layers of the same material of the first region 510 and the second region 520. The third region 530 may have the same dimensions as the dimensions of the first region 510 in the thickness direction (±z direction).

The first region 510 and the third region 530 may be the body portion BP, and the second region 520 may be the tip portion TP in contact with a connection object (circuit board 300).

The first region 510 is provided with a plurality of metal layers stacked in the thickness direction (±z direction). The plurality of metal layers are metal layers of different materials. The plurality of metal layers includes the first metal layer 101 and the second metal layer 102. The first metal layer 101 is a metal with relatively high rigidity or wear resistance compared to the second metal layer 102, and is preferably formed of a metal selected from rhodium (Rd), platinum (Pt), iridium (Ir), palladium (Pd), nickel (Ni), manganese (Mn), tungsten (W), phosphorus (Ph) or an alloy thereof, or palladium-cobalt (PdCo) alloy, palladium-nickel (PdNi) alloy, or nickel-phosphorus (NiPh) alloy, nickel-manganese (NiMn), nickel-cobalt (NiCo) or Nickel-tungsten (NiW) alloy. The second metal layer 102 is a metal with relatively high electrical conductivity compared to the first metal layer 101, and is preferably formed of a metal selected from copper (Cu), silver (Ag), gold (Au), or alloys thereof. The first metal layer 101 is provided on the lower and upper surfaces of the first region 510 in the thickness direction (±z direction), and the second metal layer 102 is provided between the first metal layers 101. For example, the first region 510 is provided by alternately stacking the first metal layer 101, the second metal layer 102, and the first metal layer 101 in that order, and the number of stacked layers may be three or more. The drawing shows that 17 metal layers are stacked.

The second region 520 may have smaller dimensions than the dimensions of the first region 510 in the thickness direction (±z direction), and may be provided in a stepped form. The second region 520 has a stacked number smaller than the number of metal layers constituting the first region 510. For example, the drawing shows eight metal layers being stacked. However, the number of metal layers constituting the second region 520 is not limited to this, and may be one or more layers, but the number is smaller than the number of metal layers constituting the first region 510. When the second region 520 is composed of a plurality of metal layers, the second region 520 includes the first metal layer 101 and the second metal layer 102, and the first metal layer 101 and the second metal layer 102 are alternately stacked.

The lowermost layer of the first region 510 is the first layer in the thickness direction (±z direction) and the uppermost layer of the first region 510 is the top layer in the thickness direction (±z direction), whereas the lowermost layer of the second region 520 is the first layer in the thickness direction (±z direction) and the uppermost layer of the second region 520 is the top layer in the thickness direction (±z direction).

The metal layers constituting the second region 520 are formed continuously of the same material as some of the metal layers constituting the first region 510. For example, the first layer (lowermost layer) in the thickness direction (±z direction) of the second region 520 is continuously formed of the same material as the tenth layer in the thickness direction (±z direction) of the first region 510, the second layer in the thickness direction (±z direction) of the second region 520 is continuously formed of the same material as the 11th layer in the thickness direction (±z direction) of the first region 510, the third layer in the thickness direction (±z direction) of the second region 520 is continuously formed of the same material as the 12th layer in the thickness direction (±z direction) of the first region 510, the fourth layer in the thickness direction (±z direction) of the second region 520 is continuously formed of the same material as the 13th layer in the thickness direction (±z direction) of the first region 510, the fifth layer in the thickness direction (±z direction) of the second region 520 is continuously formed of the same material as the 14th layer in the thickness direction (±z direction) of the first region 510, the sixth layer in the thickness direction (±z direction) of the second region 520 is continuously formed of the same material as the 15th layer in the thickness direction (±z direction) of the first region 510, the seventh layer in the thickness direction (±z direction) of the second region 520 is continuously formed of the same material as the 16th layer in the thickness direction (±z direction) of the first region 510, and the eighth layer in the thickness direction (±z direction) of the second region 520 is continuously formed of the same material as the 17th layer in the thickness direction (±z direction) of the first region 510.

The uppermost layer of the second region 520 is formed continuously of the same material as the uppermost layer of the first region 510, and the lowermost layer of the second region 520 is formed continuously of the same material as one of the internal metal layers of the first region 510. In a structure where the second region 520 and the first region 510 are discontinuously formed from different materials, problems arise where electrical resistance increases at discontinuous boundaries. However, in a configuration in which metal layers of the same material are continuously formed in the second region 520 and the first region 510 as in the preferred embodiment of the present disclosure, the problem of increased electrical resistance does not occur.

The lowermost and the uppermost layers of the first region 510 are composed of the first metal layer 101.

The lowermost layer of the second region 520 is composed of the second metal layer 102 and the uppermost layer of the second region 520 is composed of the first metal layer 101. In this case, the second region 520 includes the first metal layer 101 and the second metal layer 102. In a configuration in which the second region 520 includes different first and second metal layers 101 and 102, electrical conductivity at the second region 520 may be improved compared to the case where the second region 520 consists only of the first metal layer 101, and the wear resistance of the second region 520 may be improved compared to the case where the second region 520 consists only of the second metal layer 102.

The lowermost layer of the third region 530 is composed of the second metal layer 102 and the uppermost layer of the third region 530 is composed of the first metal layer 101.

The metal layer of the third region 530 includes: a first connection portion 531 made of the same material as the metal layer of the first region 510; a second connection portion 532 made of the same material as the metal layer of the second region 520; and a middle portion 533 connecting the first connection portion 531 and the second connection portion 532. However, depending on the number of metal layers constituting the third region 530, the middle portion 533 may be directly connected to the metal layer of the first region 510 without the first connection portion 531, or the middle portion 533 may be directly connected to the metal layer of the second region 520 without the second connection portion 532.

Although the middle portion 533 of the third region 530 is shown in a vertical form in the drawings, when manufactured through a plating process, the second region 520 and the third region 530 may be concave in the −z direction.

Any one of the metal layers constituting the second region 520 and the third region 530 may contact a plurality of metal layers of the first region 510. Specifically, the metal layer constituting the lowermost layers of the second region 520 and the third region 530 is in contact with the plurality of metal layers of the first region 510. Except for the lowermost layers of the second region 520 and the third region 530, each of the remaining metal layers is made of the same material as the metal layer of the first region 510 and the metal layer of the second region 520 and is connected in a one-to-one correspondence. For example, as shown in the drawing, the metal layers of the first to ninth layers of the first region 510 are in contact with the metal layer constituting the lowermost layer of the third region 530, and the metal layers of the 10th to 17th layers of the first region 510 are made of the same material as the respective metal layers of the third region 530 and are continuously extended.

The lowermost layers of the second region 520 and the third region 530 are formed of the second metal layer 102 with high electrical conductivity so as to be integrally connected to the second metal layer 102 with high electrical conductivity provided inside the first region 510. Accordingly, all of the second metal layers 102 with high electrical conductivity provided in the second region 520 are integrally connected to the second metal layer 102 with high electrical conductivity provided in the first region 510. As a result, electricity flows smoothly from the tip portion TP to the body portion BP or from the body portion BP to the tip portion TP through the second metal layers 102, thereby improving electrical conductivity.

In addition, since all of the first metal layers 101 with high elastic strength provided in the second region 520 are integrally and continuously connected to some of the first metal layers 101 with high elastic strength provided in the first region 510, it is possible to prevent the tip portion TP from being easily separated from the body portion BP or damaged.

The electrically conductive contact pin 200 is provided with: a first-side enlarged portion 212 caught on the upper surface of the upper guide plate GP1; and a second-side concave portion 213 provided on the opposite side of the first-side enlarged portion. The first-side enlarged portion 212 is provided to protrude from the body portion BP in one direction of the width direction (±x direction). On the opposite side of the first-side enlarged portion 212, the second-side concave portion 213 is provided. The second-side concave portion 213 is provided in a concave shape in the same direction as the direction in which the first-side enlarged portion 212 protrudes. As shown in FIG. 8, a plurality of electrically conductive contact pins 200 are installed on the guide plates GP1 and GP2. At this time, a first-side enlarged portion 212, a second-side concave portion 213, a first-side enlarged portion 212, and a second-side concave portion 213 are arranged in that order, so that at a position corresponding to the first-side enlarged portion 212 of one electrically conductive contact pin 200, the second-side concave portion 213 of the other electrically conductive contact pin 200 is located. Due to this, even if the electrically conductive contact pins 200 are arranged at a narrow pitch, short-circuit problems may be prevented. (Meanwhile, in FIG. 8, the pitch of the electrically conductive contact pins 200 is shown to be somewhat exaggerated, but it will be appreciated that the pins 200 may be arranged at a narrower pitch than this.)

An upper tip portion 221 of the electrically conductive contact pin 200 is connected to a pad CP of the circuit board 300. In this case, the circuit board 300 is a part that constitutes a circuit unit to inspect the inspection object, including a space converter. A lower tip portion 222 of the electrically conductive contact pin 200 is connected to the terminal of the inspection object. The upper tip portion 221 of the electrically conductive contact pin 200 has dimensions smaller than the dimensions of the body portion BP in the thickness direction (±z direction), and the upper tip portion 221 has a stacked number smaller than the number of stacked metal layers constituting the body portion BP. This increases the tracking pressure and improves the reliability of the connection by providing high electrical conductivity and high strength.

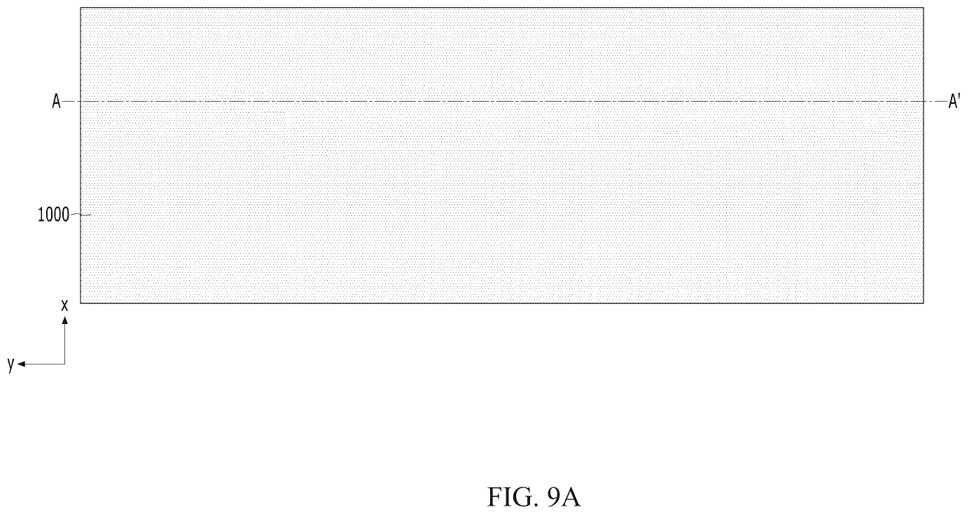

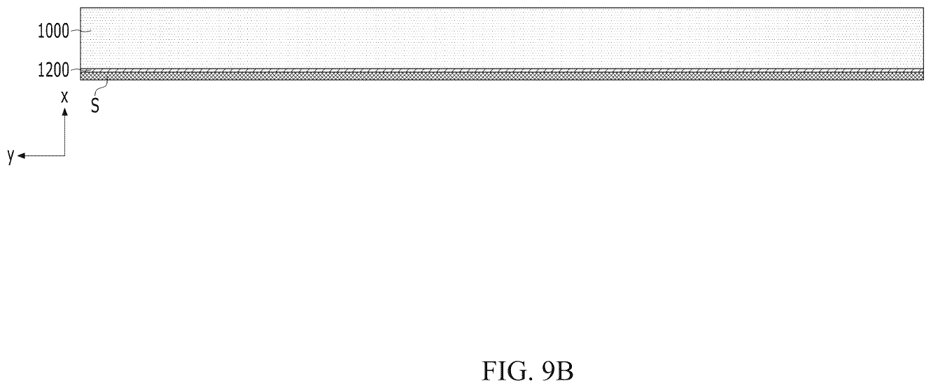

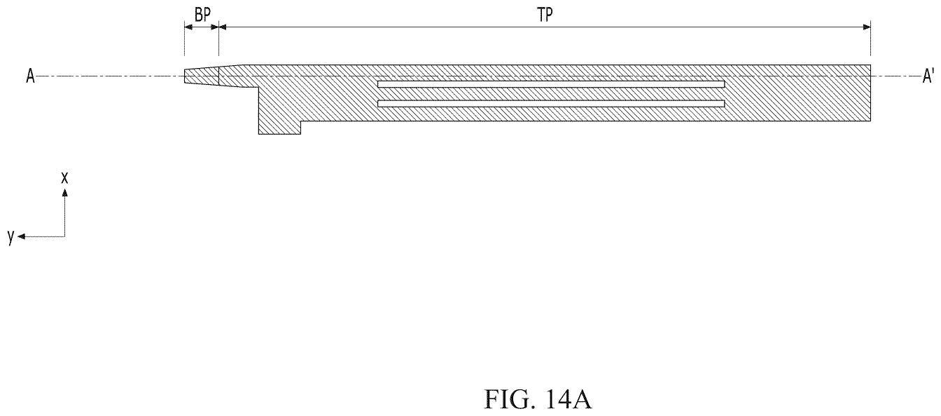

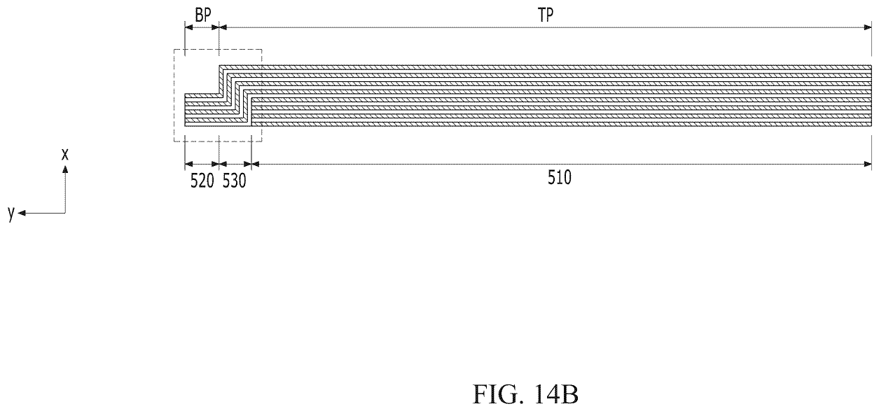

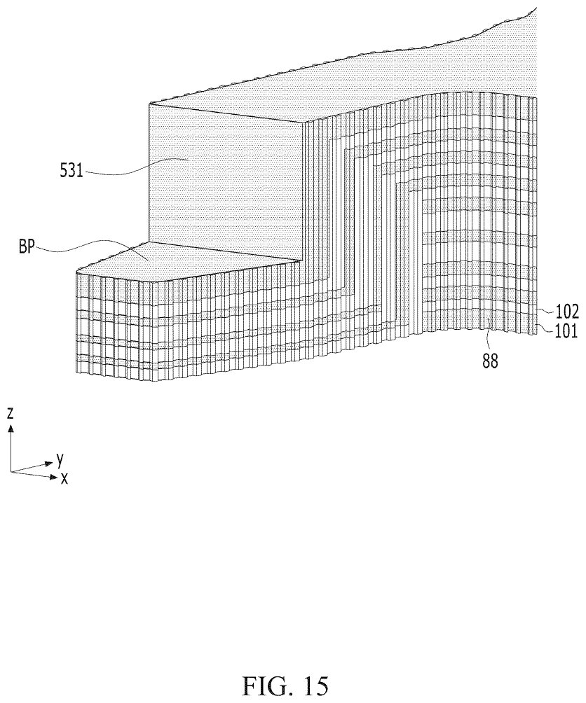

Hereinafter, a method for manufacturing the electrically conductive contact pin 200 according to the first preferred embodiment of the present disclosure will be described. FIGS. 9A to 14B are views showing a method for manufacturing the electrically conductive contact pin 200 according to the first preferred embodiment of the present disclosure, and FIG. 15 is an enlarged perspective view of part B of FIG. 14B.

First, a mold 1000 is prepared. FIG. 9A is a plan view of the mold 1000 and FIG. 9B is a cross-sectional view taken along line A-A′ of FIG. 9A.

The mold 1000 may be made of an anodic oxide film, a photoresist, a silicon wafer, or similar materials. However, preferably, the mold 1000 may be made of an anodic oxide material. The anodic oxide film refers to a film formed by anodizing a base metal, and a pore refers to a hole formed in the process of anodizing a metal to form the anodic oxide film. For example, assuming that the base metal is aluminum (Al) or an aluminum alloy, when the base metal is anodized, an anodic oxide film made of aluminum oxide (Al2O3) is formed on the surface of the base metal.

However, the base metal is not limited to aluminum (Al) or an aluminum alloy and includes Ta, Nb, Ti, Zr, Hf, Zn, W, Sb, or alloys thereof. The anodic oxide film formed as above is vertically divided into a barrier layer without pores formed thereinside and a porous layer with pores formed thereinside. When the base material is removed from the base material on which the anodic oxide film having the barrier layer and the porous layer is formed on the surface, only the anodic oxide film made of aluminum oxide (Al2O3) remains. The anodic oxide film may be formed in a structure in which the top and bottom of the pore are penetrated as the barrier layer formed during anodization is removed, or may be formed in a structure in which the top and bottom ends of the pore are sealed as the barrier layer formed during anodization remains intact.

The anodic oxide film has a thermal expansion coefficient of 2˜3 ppm/° C. For this reason, when exposed to a high temperature environment, thermal deformation due to temperature is small. Therefore, even if the production environment for the electrically conductive contact pin 200 is a high temperature environment, the electrically conductive contact pin 200 may be manufactured with precision without thermal deformation.

Conventionally, molds for manufacturing electrically conductive contact pins were manufactured using photoresist (PR) instead of an anodic oxide film. As the mold is manufactured by repeating the process of spraying and hardening the liquid photoresist, layers are created in 30 μm units. Even after the electrically conductive contact pin is completed, a joint like a bamboo node is formed at each layer change, making it prone to deformation. There were limits to stacking molds high, and precise patterning was also difficult. However, such a problem may be solved by using the mold 1000 made of an anodic oxide material. First, since the anodic oxide film that is already in a solid state is etched, precise patterning is possible. In addition, unlike the conventional method, the completed electrically conductive contact pin 200 did not have any layer joints and did not deform after use. Electrical conductivity is also higher than that of existing pins, and the pin 200 may be used without signal loss even in high frequency bands above 100 GHz (gigahertz).

Since the electrically conductive contact pin 200 according to the preferred embodiment of the present disclosure is manufactured using the mold 1000 of an anodic oxide material instead of a photoresist-based mold, it is possible to demonstrate the effect of realizing precise and fine shapes, which were limited in realization with photoresist molds. In addition, with an existing photoresist mold, an electrically conductive contact pin with a thickness of about 40 μm may be manufactured, but when using the mold 1000 of an anodic oxide material, it is possible to manufacture an electrically conductive contact pin 200 with a thickness of 100 μm or more and 200 μm or less. Due to this, multilayer plating using the first and second metal layers 101 and 102 is possible, thereby improving elastic strength and electrical conductivity at the same time.

A seed layer 1200 is provided on the lower surface of the mold 1000. The seed layer 1200 may be provided on the lower surface of the mold 1000 before forming the first internal space 1100 in the mold 1000. Meanwhile, a support substrate S is provided below the mold 1000 to improve the handling of the mold 1000. The seed layer 1200 is made of a different metal material than that of the first and second metal layers 101 and 102. The seed layer 1200 may be formed of, for example, copper (Cu), and may be formed by deposition.

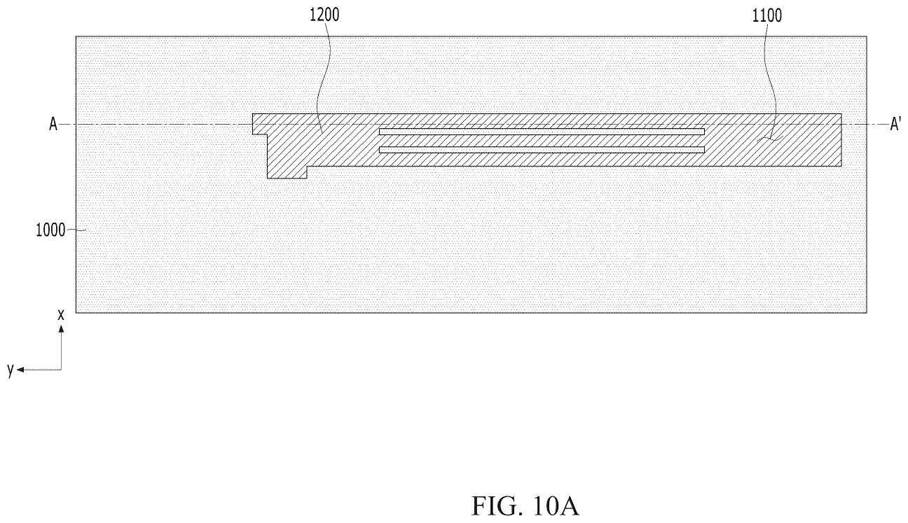

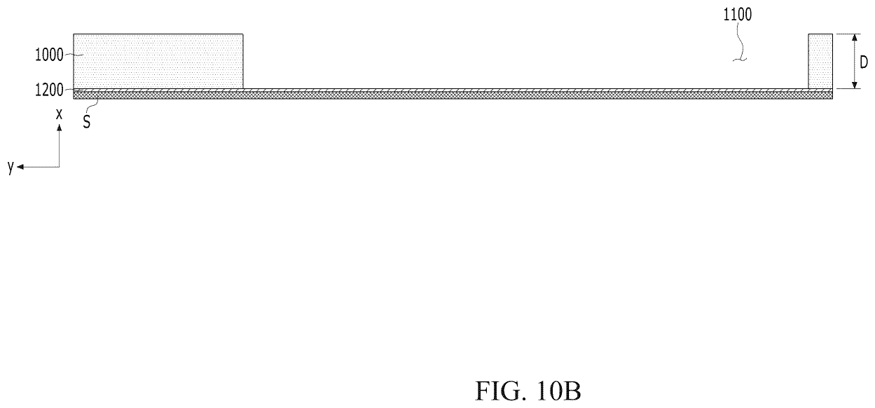

Next, the step of forming a first internal space 1100 by removing a part of the mold 1000 is performed. FIG. 10A is a plan view showing the first internal space 1100 formed in the mold 1000, and FIG. 10B is a cross-sectional view taken along line A-A′ of FIG. 10A.

The first internal space 1100 may be formed by wet etching the mold 1000 of an anodic oxide material. To this end, a photoresist is provided on the upper surface of the mold 1000 and patterned, and then the anodic oxide film in the patterned open area reacts with the etching solution to form the first internal space 1100.

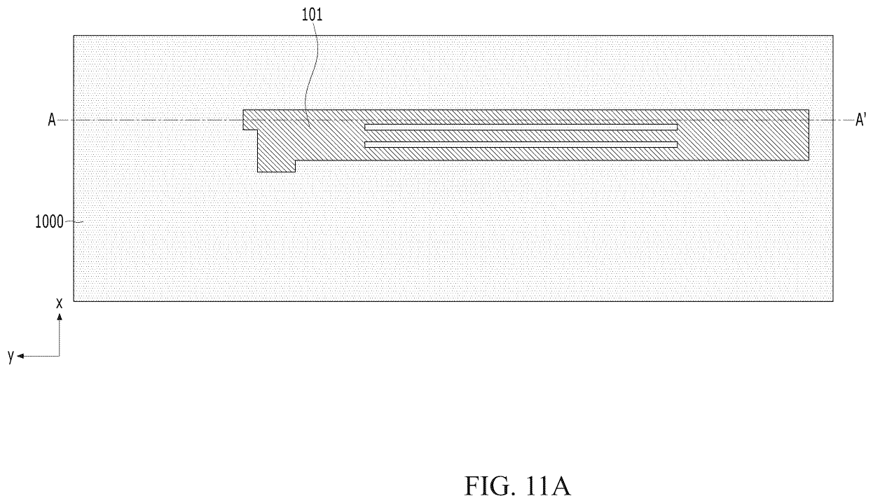

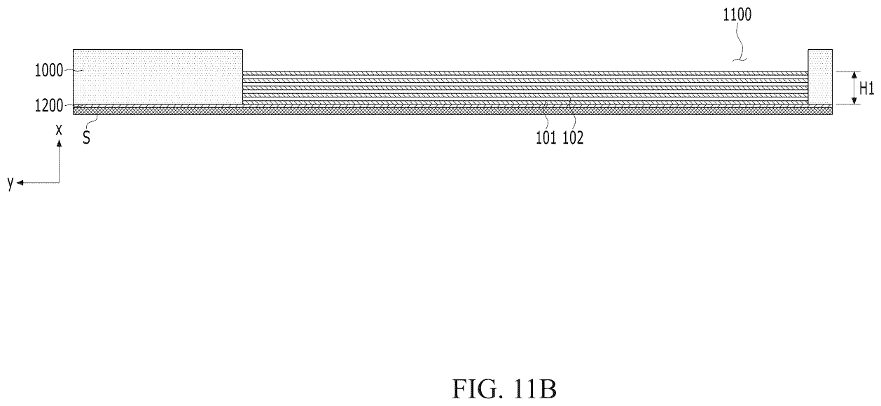

Next, the step of forming a metal layer in a first height section H1 of the first internal space 1100 is performed. FIG. 11A is a plan view showing a state in which multilayer plating is performed on the first height section H1 of the first internal space 1100, and FIG. 11B is a cross-sectional view taken along line A-A′ of FIG. 11A.

An electroplating process is performed using the seed layer 1200 to form a metal layer in the first internal space 1100, and the metal layer is formed only up to the first height section H1 of the first internal space 1100. The first height section H1 is smaller than a thickness D of the mold 1000.

Because the metal layer is formed as it grows in the thickness direction (±z direction) of the mold 1000, the shape of each cross section in the thickness direction (±z direction) of the mold 1000 is the same, and a plurality of metal layers are stacked in the thickness direction (±z direction) of the mold 1000. The plurality of metal layers includes the first metal layer 101 and the second metal layer 102. The first metal layer 101 is a metal with relatively high wear resistance compared to the second metal layer 102, and includes rhodium (Rd), platinum (Pt), iridium (Ir), palladium (Pd) or an alloy thereof, or palladium-cobalt (PdCo) alloy, palladium-nickel (PdNi) alloy, or nickel-phosphorus (NiPh) alloy, nickel-manganese (NiMn), nickel-cobalt (NiCo) or Nickel-tungsten (NiW) alloy. The second metal layer 102 is a metal with relatively high electrical conductivity compared to the first metal layer 101, and includes copper (Cu), silver (Ag), gold (Au), or an alloy thereof.

The first metal layer 101 is provided on the lowermost and uppermost layers in the thickness direction (±z direction), and the second metal layer 102 is provided between the first metal layers 101. For example, a plurality of metal layers is provided by alternately stacking the first metal layer 101, the second metal layer 102, and the first metal layer 101, and the number of stacked layers may be three or more.

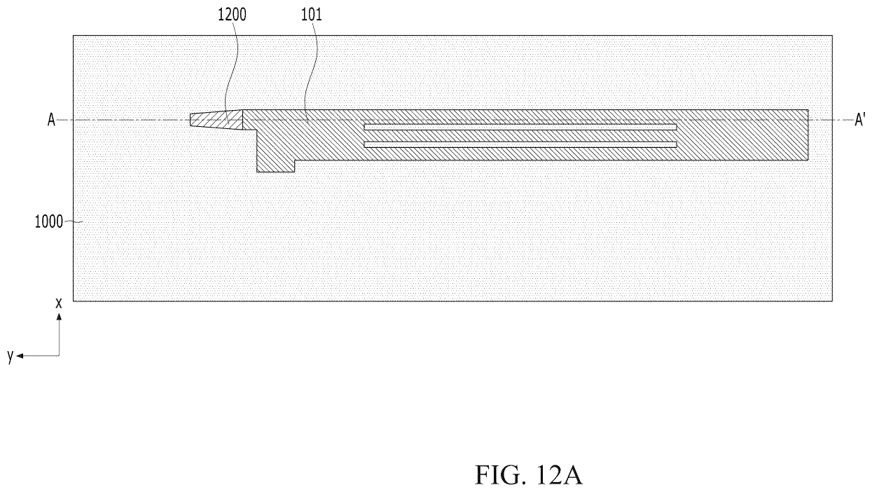

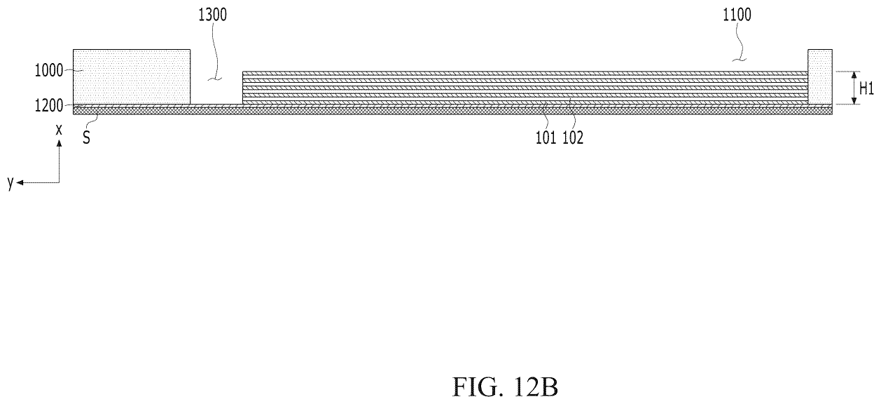

Next, the step of removing a part of the mold 1000 and forming a second internal space 1300 in communication with the first internal space 1100 is performed. FIG. 12A is a plan view showing a state in which the second internal space 1300 is formed by removing a portion of the mold 1000, and FIG. 12B is a cross-sectional view taken along line A-A′ of FIG. 12A.

A photoresist is provided on the upper surface of the mold 1000 and patterned, and then the anodic oxide film in the patterned open area reacts with the etching solution to form the second internal space 1300. The second internal space 1300 is formed to communicate with the first internal space 1100.

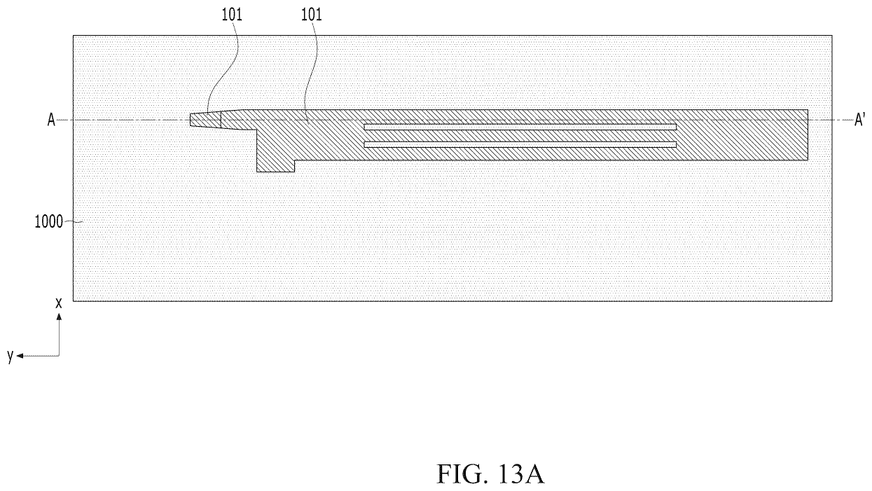

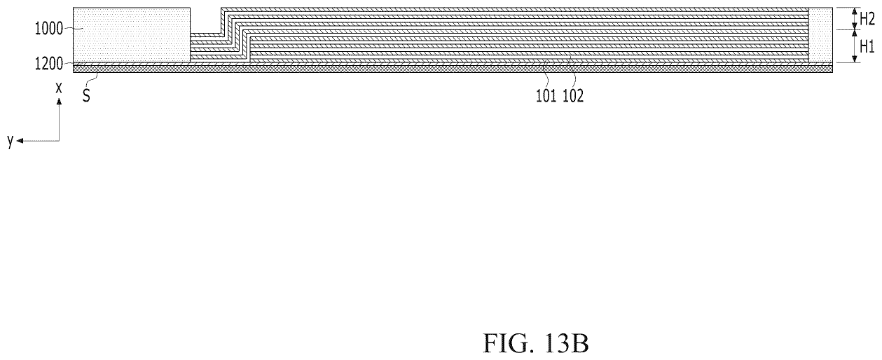

Next, the step of forming a metal layer in a second height H2 section of the first internal space 1100 and in the second internal space 1300 is performed. FIG. 13A is a plan view showing a state in which a metal layer is formed in the second height H2 section of the first internal space 1100 and the second internal space 1300, and FIG. 13B is a cross-sectional view taken along line A-A′ of FIG. 13A.

The metal layer is formed in the second height section H2 of the first internal space 1100 and the second internal space 1300. A metal layer is already formed in the first height section H1 of the first internal space 1100, and the already formed metal layer also functions as a seed layer. Since the metal layer already formed in the previous step functions as a seed layer, the metal layers additionally formed in the second height section H2 of the first internal space 1100 and in the second internal space 1300 may be provided in a concave round shape in the −z direction.

The additionally formed metal layer is provided by stacking a plurality of metal layers in the thickness direction (±z direction) of the mold 1000. The plurality of metal layers includes the first metal layer 101 and the second metal layer 102. The first metal layer 101 is a metal with relatively high wear resistance compared to the second metal layer 102, and includes rhodium (Rd), platinum (Pt), iridium (Ir), palladium (Pd) or an alloy thereof, or palladium-cobalt (PdCo) alloy, palladium-nickel (PdNi) alloy, or nickel-phosphorus (NiPh) alloy, nickel-manganese (NiMn), nickel-cobalt (NiCo) or Nickel-tungsten (NiW) alloy. The second metal layer 102 is a metal with relatively high electrical conductivity compared to the first metal layer 101, and includes copper (Cu), silver (Ag), gold (Au), or an alloy thereof.

Accordingly, the metal layer formed in the first height section H1 and the second height section H2 of the first internal space 1100 becomes a first region 511, and the metal layers formed in the second internal space 1300 become second and third regions 520 and 530.

When the plating process is completed, a process to remove the mold 1000 and the seed layer 1200 is performed. If the mold 1000 is made of an anodic oxide material, the mold 1000 is removed using a solution that selectively reacts with the anodic oxide material. In addition, if the seed layer 1200 is made of copper (Cu), the seed layer 1200 is removed using a solution that selectively reacts with copper (Cu).

Meanwhile, gold (Au) may be additionally provided on the entirety of or partially on the outermost surface of the electrically conductive contact pin 200.

According to the manufacturing method described above, by using one mold 1000, but forming part of the first region 510 in the first internal space 1100 formed by the first etching process and forming first to third regions 510, 520, and 530 in the second internal space 1300 and the first internal space 1100 formed by the second etching process, a stepped second region 520 is produced. In this way, a stepped tip portion TP at the end of the body portion BP may be manufactured by etching the mold 1000 using one mold 1000. On the other hand, when manufacturing an electrically conductive contact pin 200 having a tip portion using photoresist, a process of stacking photoresist that functions as a mold multiple times is necessary. As a result, the process is complicated, and due to the photoresist-based mold stacked multiple times, a node is created for each layer on the side of the electrically conductive contact pin 200. However, according to the manufacturing method according to the preferred embodiment of the present disclosure, since a plating space is formed by etching using a single mold 1000, a stepped tip portion TP may be formed and no node is created at each layer.

Referring to FIG. 15, the electrically conductive contact pin 200 according to the preferred embodiments of the present disclosure includes a plurality of fine trenches 88 on the side thereof. The fine trench 88 is formed to extend long from the side of the electrically conductive contact pin 200 in the thickness direction (±z direction) of the electrically conductive contact pin 200. In this case, the thickness direction (±z direction) of the electrically conductive contact pin 200 refers to the direction in which the metal layer grows during electroplating.

The fine trench 88 is formed on all sides of the first region 510, the second region 520, and the third region 530. Additionally, the fine trench 88 is formed on both the side surface of the body portion BP and the side surface of the tip portion TP. However, the fine trench 88 is not provided on an end surface 531 of the electrically conductive contact pin 200. The end surface 531 is a stepped surface of the body portion BP formed by stepping from the body portion BP toward the tip portion TP.

The fine trench 88 has a depth ranging from 20 nm to 1 μm, and its width also ranges from 20 nm to 1 μm. In this case, since the fine trench 88 is caused by a pore created during the manufacture of the anodic oxide film mold 1000, the width and depth of the fine trench 88 have values less than the range of the diameter of the pore of the anodic oxide film mold 1000. Meanwhile, in the process of forming the first and second internal spaces 1100 and 1300 in the anodic oxide film mold 1000, at least some of the pores of the anodic oxide film mold 1000 may be crushed by the etching solution to form at least some of the fine trenches 88 with a depth that is greater than the diameter of the pore created during anodization.

Because the anodic oxide film mold 1000 includes numerous pores, and at least a portion of the anodic oxide film mold 1000 is etched to form the first and second internal spaces 1100 and 1300, and a metal layer is formed inside the first and second internal spaces 1100 and 1300 by electroplating, the side of the electrically conductive contact pin 200 is provided with fine trenches 88 that are formed while contacting the pores of the anodic oxide film mold 1000.

The fine trench 88 as above has the effect of increasing the surface area on the side of the electrically conductive contact pin 200. Due to the configuration of the fine trenches 88 formed on the side of the electrically conductive contact pin 200, heat generated in the electrically conductive contact pin 200 may be quickly dissipated, thereby suppressing the temperature rise of the electrically conductive contact pin 200. In addition, due to the configuration of the fine trenches 88 formed on the side of the electrically conductive contact pin 200, the ability to resist torsion may be improved when the electrically conductive contact pin 200 is deformed.

Meanwhile, in the process of automatically inserting the electrically conductive contact pin 200 into the guide holes of the guide plate GP1 and GP2 using a means of a robot, a process of confirming the location of the electrically conductive contact pin 200 is performed by imaging the electrically conductive contact pin 200. At this time, the fine trench 88 formed on the side of the electrically conductive contact pin 200 functions as a diffuse reflection surface when photographed by an imaging device, allowing the imaging device to accurately determine the position of the electrically conductive contact pin 200. In addition, since the end surface 531 of the electrically conductive contact pin 200 is not provided with a fine trench 88, when photographing the electrically conductive contact pin 200 using the imaging device, through contrast between the area provided with the fine trench 88 and the end surface 531 without the fine trench 88, the position of the end surface 531 of the electrically conductive contact pin 200 may be precisely determined.

### Second Embodiment

Next, a second embodiment according to the present disclosure will be described. However, the description will focus on characteristic components compared to the first embodiment, and descriptions of components that are the same or similar to that of the first embodiment will be omitted if possible.

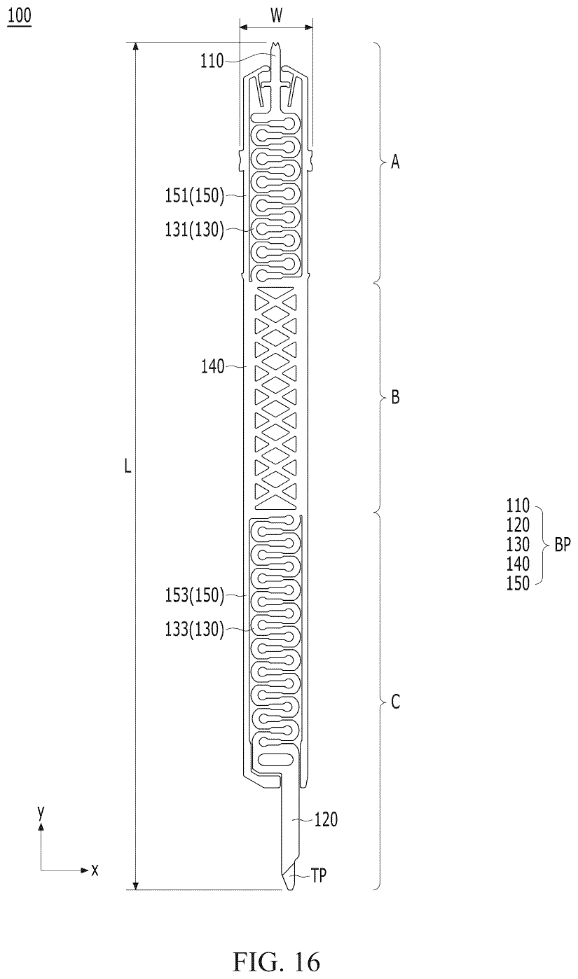

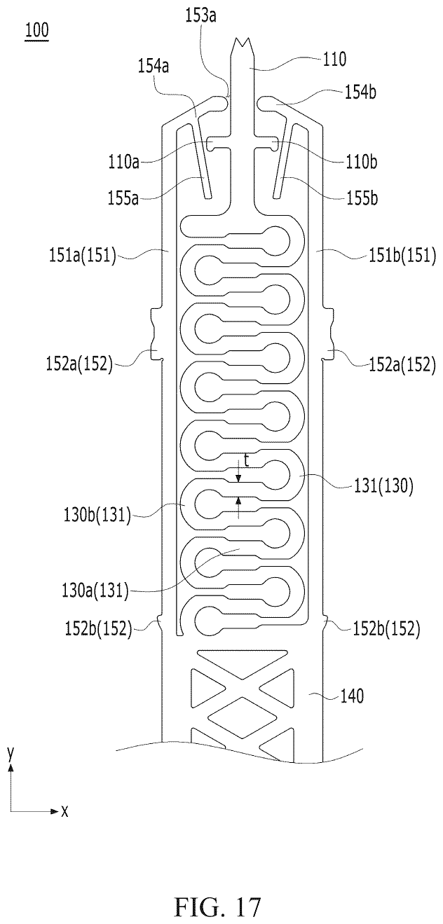

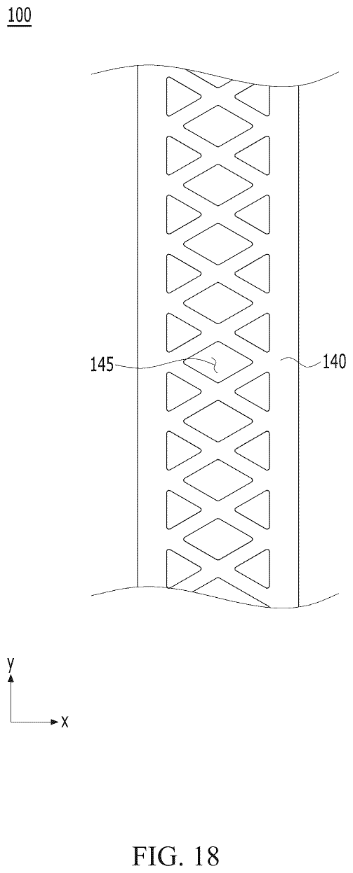

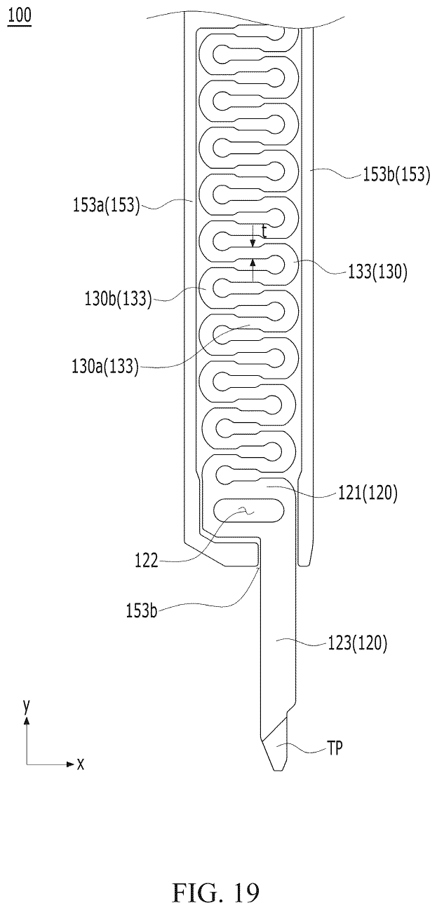

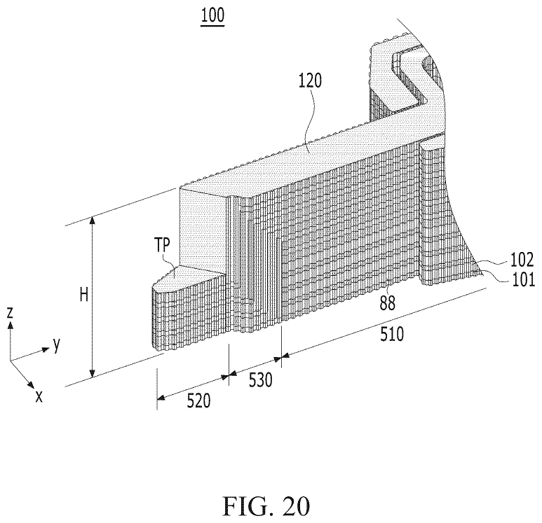

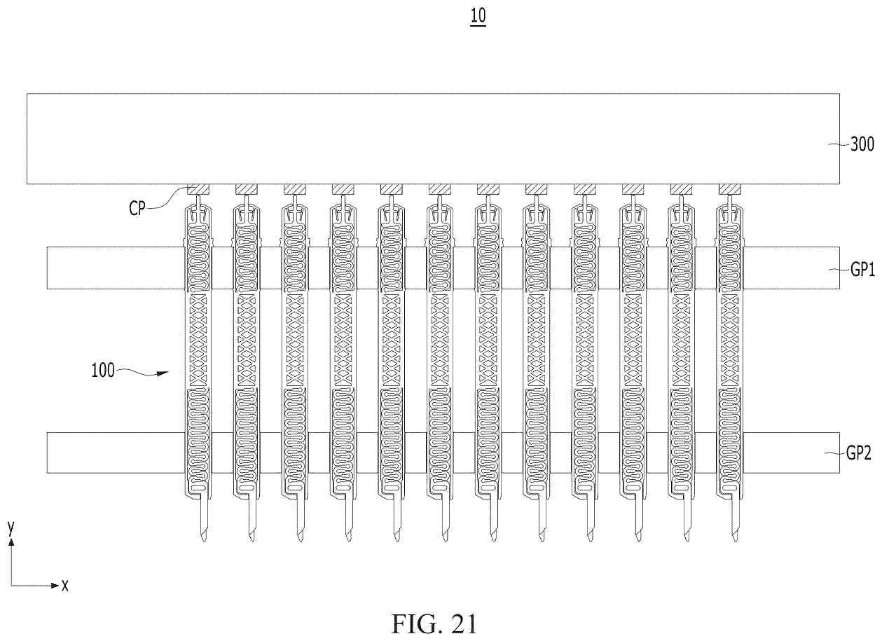

FIG. 16 is a plan view of an electrically conductive contact pin 100 according to the second preferred embodiment of the present disclosure; FIG. 17 is an enlarged view of part A of FIG. 16; FIG. 18 is an enlarged view of part B of FIG. 16; FIG. 19 is an enlarged view of part C of FIG. 16; FIG. 20 is a partially enlarged perspective view of FIG. 19; and FIG. 21 is a view showing an inspection device 10 equipped with the electrically conductive contact pin 100 according to the second preferred embodiment of the present disclosure.

The electrically conductive contact pin 100 includes: a body portion BP composed of multiple metal layers stacked in the thickness direction; and a tip portion TP provided on at least one of a front-end portion and a base-end portion of the body portion BP.

The body portion BP includes a first connection portion 110, a second connection portion 120, an elastic portion 130, an inelastic portion 140, and an outer wall portion 150, which will be described below. The tip portion TP is TP provided on at least one of the first connection portion 110, which is the front-end portion of the body portion BP, and the second connection portion 120, which is the base-end portion of the body portion BP.

The body portion BP includes the elastic portion 130 formed by bending a plate and is elastically deformed in the length direction (±y direction).

The body portion BP is provided with a plurality of metal layers stacked in the thickness direction (±z direction). The plurality of metal layers are metal layers of different materials. The plurality of metal layers includes a first metal layer 101 and a second metal layer 102. The first metal layer 101 is a metal with relatively high rigidity or wear resistance compared to the second metal layer 102, and is preferably made of a metal selected from rhodium (Rd), platinum (Pt), iridium (Ir), palladium (Pd), nickel (Ni), manganese (Mn), tungsten (W), phosphorus (Ph) or an alloy thereof, or palladium-cobalt (PdCo) alloy, palladium-nickel (PdNi) alloy, or nickel-phosphorus (NiPh) alloy, nickel-manganese (NiMn), nickel-cobalt (NiCo) or Nickel-tungsten (NiW) alloy. The second metal layer 102 is a metal with relatively high electrical conductivity compared to the first metal layer 101, and is preferably formed of a metal selected from copper (Cu), silver (Ag), gold (Au), or alloys thereof.

The first metal layer 101 is provided on the lower and upper surfaces of the body portion BP in the thickness direction (±z direction), and the second metal layer 102 is provided between the first metal layers 101. For example, the body portion BP is provided by alternately stacking the first metal layer 101, the second metal layer 102.

The lowermost layer of the body portion BP is the first layer in the thickness direction (±z direction) and the uppermost layer of the body portion BP is the top layer in the thickness direction (±z direction), whereas the lowermost layer of the tip portion TP is the first layer in the thickness direction (±z direction) and the uppermost layer of the tip portion TP is the top layer in the thickness direction (±z direction).

The tip of the body portion BP is on the circuit board 300 side, and the lower end of the body portion BP is the inspection object side. The tip portion TP is provided on at least one of the front-end portion and the base-end portion of the body portion BP. Referring to the drawings, the tip portion TP is provided at the base-end portion of the body portion BP. The present disclosure is not limited to this, and the tip portion TP may be provided at the front-end portion of the body portion BP.

The tip portion TP has smaller dimensions than the dimensions of the body portion BP in the width direction (±x direction).

The tip portion TP has smaller dimensions than the dimensions of the body portion BP in the thickness direction (±z direction), and is provided in a stepped form. The lower surface of the tip portion TP is located on the same plane as the lower surface of the body portion BP, and the upper surface of the tip portion TP is located at a lower height than the upper surface of the body portion BP. In this case, the lower surface of the tip portion TP is the bottom layer in the thickness direction (±z direction) and the upper surface of the tip portion TP is the top layer in the thickness direction (±z direction).

The tip portion TP has a stacked number smaller than the number of metal layers constituting the body portion BP. To be specific, the tip portion TP is composed of at least one metal layer. For example, the drawing shows eight metal layers being stacked. However, the number of metal layers constituting the tip portion TP is not limited to this, and may be one or more layers, but the number is smaller than the number of metal layers constituting the body portion BP.

The metal layers constituting the tip portion TP are formed continuously of the same material as some of the metal layers constituting the body portion BP. For example, the first layer (lowermost layer) in the thickness direction (±z direction) of the tip portion TP is continuously formed of the same material as the tenth layer in the thickness direction (±z direction) of the body portion BP, the second layer in the thickness direction (±z direction) of the tip portion TP is continuously formed of the same material as the 11th layer in the thickness direction (±z direction) of the body portion BP, the third layer in the thickness direction (±z direction) of the tip portion TP is continuously formed of the same material as the 12th layer in the thickness direction (±Z direction) of the body portion BP, the fourth layer in the thickness direction (±z direction) of the tip portion TP is continuously formed of the same material as the 13th layer in the thickness direction (±z direction) of the body portion BP, the fifth layer in the thickness direction (±z direction) of the tip portion TP is continuously formed of the same material as the 14th layer in the thickness direction (±z direction) of the body portion BP, the sixth layer in the thickness direction (±z direction) of the tip portion TP is continuously formed of the same material as the 15th layer in the thickness direction (±z direction) of the body portion BP, the seventh layer in the thickness direction (±z direction) of the tip portion TP is continuously formed of the same material as the 16th layer in the thickness direction (±z direction) of the body portion BP, and the eighth layer in the thickness direction (±z direction) of the tip portion TP is continuously formed of the same material as the 17th layer in the thickness direction (±z direction) of the body portion BP.

The uppermost layer of the tip portion TP is formed continuously of the same material as the uppermost layer of the body portion BP, and the lowermost layer of the tip portion TP is formed continuously of the same material as one of the internal metal layers of the body portion BP. In addition, the metal layer between the lowermost layer of the tip portion TP and the uppermost layer of the tip portion TP is continuously formed of the same material as the inner metal layer of the body portion BP.

In a structure where the tip portion TP and the body portion BP are discontinuously formed from different materials, problems arise where electrical resistance increases at discontinuous boundaries. However, in a configuration in which metal layers of the same material are continuously formed in the tip portion TP and the body portion BP as in the preferred embodiment of the present disclosure, since the flow of electricity from the tip portion TP to the body portion BP is continuous, the problem of increased electrical resistance at the discontinuous boundary as in the conventional case does not occur. In addition, since the metal layers constituting the tip portion TP and the body portion BP are made of the same metal material and are continuous, the problem of the tip portion TP being separated from the body portion BP may be minimized.

The material of the first metal layer 101 corresponding to the 1st, 3rd, 5th, 7th, and 9th layers of the body portion BP and the material of the first metal layer 101 corresponding to the 11th, 13th, 15th, and 17th layers of the body portion BP may be a metal of the same material or a metal of a different material among the metals included in the first metal layer 101. In addition, the material of the second metal layer 102 corresponding to the 2nd, 4th, 6th, and 8th layers of the body portion BP and the material of the second metal layer 102 corresponding to the 10th, 12th, 14th, and 16th layers of the body portion BP may be a metal of the same material or a metal of a different material among the metals included in the second metal layer 102.

Considering the wear resistance of the body portion BP, the lowermost and uppermost layers of the body portion BP may be composed of the first metal layer 101.

The lowermost layer of the tip portion TP may be composed of the second metal layer 102 and the uppermost layer of the tip portion TP may be composed of the first metal layer 101. In this case, the tip portion TP is composed of a plurality of metal layers, including a first metal layer 101 and a second metal layer 102, stacked in the thickness direction (±z direction). In a configuration in which the tip portion TP includes different first and second metal layers 101 and 102, electrical conductivity at the tip portion TP may be improved compared to the case where the tip portion TP consists only of the first metal layer 101, and the rigidity and wear resistance of the tip portion TP may be improved compared to the case where the tip portion TP consists only of the second metal layer 102.

Meanwhile, the lowermost and uppermost layers of the tip portion TP may be composed of the second metal layer 102. In this case, the first metal layer 101 may be provided between the lowermost and uppermost layers of the tip portion TP. In a configuration in which the tip portion TP includes different first and second metal layers 101 and 102, electrical conductivity at the tip portion TP may be improved compared to the case where the tip portion TP consists only of the first metal layer 101, and the rigidity of the tip portion TP may be improved compared to the case where the tip portion TP consists only of the second metal layer 102.

Meanwhile, the lowermost and uppermost layers of the tip portion TP may be composed of the first metal layer 101. In this case, the second metal layer 102 may be provided between the lowermost and uppermost layers of the tip portion TP. In a configuration in which the tip portion TP includes different first and second metal layers 101 and 102, electrical conductivity at the tip portion TP may be improved compared to the case where the tip portion TP consists only of the first metal layer 101, and the rigidity and wear resistance of the tip portion TP may be improved compared to the case where the tip portion TP consists only of the second metal layer 102.

Meanwhile, the tip portion TP may be provided as a single metal layer. The single metal layer may be the first metal layer 101 or the second metal layer 102. In this case as well, the single metal layer constituting the tip portion TP is continuously formed of the same material as the metal layer constituting the body portion BP.

For example, the first metal layer 101 constituting the tip portion TP and the body portion BP may be a palladium-cobalt (PdCo) alloy, and the second metal layer 102 may be gold (Au). All of the second metal layers 102 made of gold (Au) constituting the body portion BP are connected to the second metal layer 102 made of gold (Au) constituting the tip portion TP. Because all of the second metal layers 102 constituting the body portion BP are integrally connected to the second metal layer 102 constituting the tip portion TP, electricity flows continuously from the body portion BP to the tip portion TP or from the tip portion TP to the body portion BP in the second metal layer 102. As a result, the electrical conductivity of the electrically conductive contact pin 200 may be greatly improved. Conventionally, the materials of the tip portion TP and the body portion BP are different, causing resistance to electric flow at the discontinuous boundary. In contrast, according to the present disclosure in which all of the second metal layers 102 of the tip portion TP are integrally connected to all of the second metal layers 102 of the body portion BP, by eliminating resistance elements that impede electrical flow, improved electrical conductivity may be provided.

In addition, for example, the first metal layer 101 constituting the tip portion TP and the body portion BP may be a palladium-cobalt (PdCo) alloy, and the second metal layer 102 may be copper (Cu). In this case, in order to improve the electrical conductivity of the electrically conductive contact pin 200, the surface of the tip portion TP may be additionally coated with gold (Au).

In addition, for example, both the lowermost and uppermost layers of the tip portion TP may be composed of the first metal layer 101. In this case as well, the lowermost and uppermost metal layers of the tip portion TP are formed continuously of the same material as the metal layer of the body portion BP. When both the lowermost and uppermost layers of the tip portion TP are composed of the first metal layer 101, the wear resistance of the tip portion TP may be improved. In addition, when both the lowermost and uppermost layers of the tip portion TP are composed of the first metal layer 101, the second metal layer 102 is provided between the lowermost layer and the uppermost layer to improve the electrical conductivity of the tip portion TP.

In addition, for example, the tip portion TP may be composed of a single layer of the first metal layer 101. In this case as well, the first metal layer 101 of the tip portion TP is formed continuously with the first metal layer 101 of the body portion BP.

In addition, for example, the tip portion TP may be composed of a single layer of the second metal layer 102. In this case as well, the second metal layer 102 of the tip portion TP is formed continuously with the second metal layer 102 of the body portion BP.

The electrically conductive contact pin 200 is divided into a first region 510, a second region 520, and a third region 530 according to the multilayer structure of the metal layers.

The first region 510 is a region composed of a plurality of metal layers stacked in the thickness direction (±z direction). The second region 520 is a region that has smaller dimensions than the dimensions of the first region 510 in the thickness direction (±z direction) and a smaller number of metal layers than the number of metal layers constituting the first region 510. The third region 530 is located between the first region 510 and the second region 520 and connects the metal layers of the same material of the first region 510 and the second region 520. The third region 530 may have the same dimensions as the dimensions of the first region 510 in the thickness direction (±z direction).

The first region 510 and the third region 530 may be the body portion BP, and the second region 520 may be the tip portion TP in contact with a connection object (inspection object).

The first region 510 is provided with a plurality of metal layers stacked in the thickness direction (±z direction). The plurality of metal layers are metal layers of different materials. The plurality of metal layers includes the first metal layer 101 and the second metal layer 102. The first metal layer 101 is a metal with relatively high rigidity or wear resistance compared to the second metal layer 102, and is preferably formed of a metal selected from rhodium (Rd), platinum (Pt), iridium (Ir), palladium (Pd), nickel (Ni), manganese (Mn), tungsten (W), phosphorus (Ph) or an alloy thereof, or palladium-cobalt (PdCo) alloy, palladium-nickel (PdNi) alloy, or nickel-phosphorus (NiPh) alloy, nickel-manganese (NiMn), nickel-cobalt (NiCo) or Nickel-tungsten (NiW) alloy. The second metal layer 102 is a metal with relatively high electrical conductivity compared to the first metal layer 101, and is preferably formed of a metal selected from copper (Cu), silver (Ag), gold (Au), or alloys thereof. The first metal layer 101 is provided on the lower and upper surfaces of the first region 510 in the thickness direction (±z direction), and the second metal layer 102 is provided between the first metal layers 101. For example, the first region 510 is provided by alternately stacking the first metal layer 101, the second metal layer 102, and the first metal layer 101 in that order, and the number of stacked layers may be three or more. The drawing shows that 17 metal layers are stacked.

The second region 520 may have smaller dimensions than the dimensions of the first region 510 in the thickness direction (±z direction), and may be provided in a stepped form. The second region 520 has a stacked number smaller than the number of metal layers constituting the first region 510. For example, the drawing shows eight metal layers being stacked. However, the number of metal layers constituting the second region 520 is not limited to this, and may be one or more layers, but the number is smaller than the number of metal layers constituting the first region 510. When the second region 520 is composed of a plurality of metal layers, the second region 520 includes the first metal layer 101 and the second metal layer 102, and the first metal layer 101 and the second metal layer 102 are alternately stacked.

The lowermost layer of the first region 510 is the first layer in the thickness direction (±z direction) and the uppermost layer of the first region 510 is the top layer in the thickness direction (±z direction), whereas the lowermost layer of the second region 520 is the first layer in the thickness direction (±z direction) and the uppermost layer of the second region 520 is the top layer in the thickness direction (±z direction).

The metal layers constituting the second region 520 are formed continuously of the same material as some of the metal layers constituting the first region 510. For example, the first layer (lowermost layer) in the thickness direction (±z direction) of the second region 520 is continuously formed of the same material as the tenth layer in the thickness direction (±z direction) of the first region 510, the second layer in the thickness direction (±z direction) of the second region 520 is continuously formed of the same material as the 11th layer in the thickness direction (±z direction) of the first region 510, the third layer in the thickness direction (±z direction) of the second region 520 is continuously formed of the same material as the 12th layer in the thickness direction (±z direction) of the first region 510, the fourth layer in the thickness direction (±z direction) of the second region 520 is continuously formed of the same material as the 13th layer in the thickness direction (±z direction) of the first region 510, the fifth layer in the thickness direction (±z direction) of the second region 520 is continuously formed of the same material as the 14th layer in the thickness direction (±z direction) of the first region 510, the sixth layer in the thickness direction (±z direction) of the second region 520 is continuously formed of the same material as the 15th layer in the thickness direction (±z direction) of the first region 510, the seventh layer in the thickness direction (±z direction) of the second region 520 is continuously formed of the same material as the 16th layer in the thickness direction (±z direction) of the first region 510, and the eighth layer in the thickness direction (±z direction) of the second region 520 is continuously formed of the same material as the 17th layer in the thickness direction (±z direction) of the first region 510.

The uppermost layer of the second region 520 is formed continuously of the same material as the uppermost layer of the first region 510, and the lowermost layer of the second region 520 is formed continuously of the same material as one of the internal metal layers of the first region 510. In a structure where the second region 520 and the first region 510 are discontinuously formed from different materials, problems arise where electrical resistance increases at discontinuous boundaries. However, in a configuration in which metal layers of the same material are continuously formed in the second region 520 and the first region 510 as in the preferred embodiment of the present disclosure, the problem of increased electrical resistance does not occur.

The lowermost and the uppermost layers of the first region 510 are composed of the first metal layer 101.

The lowermost layer of the second region 520 is composed of the second metal layer 102 and the uppermost layer of the second region 520 is composed of the first metal layer 101. In this case, the second region 520 includes the first metal layer 101 and the second metal layer 102. In a configuration in which the second region 520 includes different first and second metal layers 101 and 102, electrical conductivity at the second region 520 may be improved compared to the case where the second region 520 consists only of the first metal layer 101, and the wear resistance of the second region 520 may be improved compared to the case where the second region 520 consists only of the second metal layer 102.

The lowermost layer of the third region 530 is composed of the second metal layer 102 and the uppermost layer of the third region 530 is composed of the first metal layer 101.

The metal layer of the third region 530 includes: a first connection portion 531 made of the same material as the metal layer of the first region 510; a second connection portion 532 made of the same material as the metal layer of the second region 520; and a middle portion 533 connecting the first connection portion 531 and the second connection portion 532. However, depending on the number of metal layers constituting the third region 530, the middle portion 533 may be directly connected to the metal layer of the first region 510 without the first connection portion 531, or the middle portion 533 may be directly connected to the metal layer of the second region 520 without the second connection portion 532.

Although the middle portion 533 of the third region 530 is shown in a vertical form in the drawings, when manufactured through a plating process, the second region 520 and the third region 530 may be concave in the −z direction.

Any one of the metal layers constituting the second region 520 and the third region 530 may contact a plurality of metal layers of the first region 510. Specifically, the metal layer constituting the lowermost layers of the second region 520 and the third region 530 is in contact with the plurality of metal layers of the first region 510. Except for the lowermost layers of the second region 520 and the third region 530, each of the remaining metal layers is made of the same material as the metal layer of the first region 510 and the metal layer of the second region 520 and is connected in a one-to-one correspondence. For example, as shown in the drawing, the metal layers of the first to ninth layers of the first region 510 are in contact with the metal layer constituting the lowermost layer of the third region 530, and the metal layers of the 10th to 17th layers of the first region 510 are made of the same material as the respective metal layers of the third region 530 and are continuously extended.

The lowermost layers of the second region 520 and the third region 530 are formed of the second metal layer 102 with high electrical conductivity so as to be integrally connected to the second metal layer 102 with high electrical conductivity provided inside the first region 510. Accordingly, all of the second metal layers 102 with high electrical conductivity provided in the second region 520 are integrally connected to the second metal layer 102 with high electrical conductivity provided in the first region 510. As a result, electricity flows smoothly from the tip portion TP to the body portion BP or from the body portion BP to the tip portion TP through the second metal layers 102, thereby improving electrical conductivity.

In addition, since all of the first metal layers 101 with high elastic strength provided in the second region 520 are integrally and continuously connected to some of the first metal layers 101 with high elastic strength provided in the first region 510, it is possible to prevent the tip portion TP from being easily separated from the body portion BP or damaged.

A first contact point of the first connection portion 110 is connected to the circuit wiring side, and the second connection part 120 is connected to the inspection object side. The elastic portion 130 allows the first connection portion 110 and the second connection portion 120 to be elastically displaced in the length direction of the electrically conductive contact pin 100. The elastic portion 130 allows the first connection portion 110 to be elastically displaced relative to the second connection portion 120 in the length direction (±y direction).

The first connection portion 110, the second connection portion 120, and the elastic portion 130 are provided as one piece. The first connection portion 110, the second connection portion 120, and the elastic portion 130 are manufactured all at once using a plating process. While the conventional pogo pin-type electrically conductive contact pin is provided by separately manufacturing a barrel and a pin portion and then assembling or combining the barrel and the pin portion, the electrically conductive contact pin 100 according to the preferred embodiment of the present disclosure differs in terms of configuration in that the first connection portion 110, the second connection portion 120, and the elastic portion 130 are manufactured all at once using a plating process so as to be provided as one piece. In addition, the conventional pogo pin-type electrically conductive contact pin has a spring formed in a spiral shape, but the elastic portion of the electrically conductive contact pin 100 according to the preferred embodiment of the present disclosure differs in terms of configuration in that the elastic portion is formed in the form of a leaf spring.

The elastic portion 130 is formed by alternately connecting a plurality of straight portions 130a and a plurality of curved portions 130b. The straight portion 130a connects the curved portions 130b adjacent to each other left and right, and the curved portion 130b connects the straight portions 130a adjacent to each other top and bottom. The curved portion 130b is provided in an arc shape.

The straight portion 130a is disposed at the center of the elastic portion 130, and the curved portion 130b is disposed at an outer portion of the elastic portion 130. The straight portion 130a is provided parallel to the width direction to make it easier to deform the curved portion 130b according to contact pressure.

The elastic portion 130 includes an upper elastic portion 131 connected to the first connection portion 110 and a lower elastic portion 133 connected to the second connection portion 120.

The inelastic portion 140 is formed between the upper elastic portion 131 and the lower elastic portion 133. The inelastic portion 140 is connected to the upper elastic portion 131 and the lower elastic portion 133 and is connected to the outer wall portion 150.

The elastic portion 130 has a cross-sectional shape in the thickness direction (±z direction) of the electrically conductive contact pin 100 that is the same in all thickness cross-sections. In addition, the elastic portion 130 has the same overall thickness. The elastic portion 130 is formed by repeatedly bending a plate with an actual width t in an S shape, and the actual width t of the plate is constant overall. The ratio of the actual width of the plate and the thickness of the plate is in the range of 1:5 or more and 1:30 or less.

Before the electrically conductive contact pin 100 inspects the inspection object, the first connection portion 110 is in contact with the circuit wiring side so that the upper elastic portion 131 may be compressed and deformed in the length direction of the electrically conductive contact pin 100, and the second connection portion 120 is not in contact with the inspection object. In the process of the electrically conductive contact pin 100 inspecting the inspection object, the second connection portion 120 may contact the inspection object and the lower elastic portion 133 may be compressed and deformed.

One end of the first connection portion 110 is a free end, and the other end of the first connection portion 110 is connected to the upper elastic portion 131 and may be elastically moved vertically by contact pressure. One end of the second connection portion 120 is a free end, and the other end of the second connection portion 120 is connected to the lower elastic portion 133 and may be elastically moved vertically by contact pressure.

The upper elastic portion 131 requires an amount of compression sufficient to enable stable contact between individual first connection portions 110 of the electrically conductive contact pins 100 and a circuit wiring portion 300. On the other hand, the lower elastic portion 133 requires an amount of compression to enable the second connection portions 120 of the electrically conductive contact pins 100 to make stable contact with the inspection objects. Thus, the spring coefficient of the upper elastic portion 131 and the spring coefficient of the lower elastic portion 133 are different from each other. For example, the lengths of the upper elastic portion 131 and the lower elastic portion 133 are provided differently. In addition, the length of the lower elastic portion 133 in the length direction may be longer than the length of the upper elastic portion 131 in the length direction.

One end of the upper elastic portion 131 is connected to the first connection portion 110 and the other end of the upper elastic portion 131 is connected to the inelastic portion 140. One end of the lower elastic portion 133 is connected to the second connection portion 120 and the other end of the lower elastic portion 133 is connected to the inelastic portion 140. The elastic portion 130 connected to the inelastic portion 140 is the curved portion 130b of the elastic portion 130. Due to this, the upper elastic portion 131 and the lower elastic portion 133 maintain elasticity with respect to the inelastic portion 140.

The upper elastic portion 131 is provided above the inelastic portion 140, and the lower elastic portion 133 is provided below the inelastic portion 140. By the inelastic portion 140, the area provided with the upper elastic portion 131 and the area provided with the lower elastic portion 133 are distinguished from each other. The upper elastic portion 131 and the lower elastic portion 133 are compressed or stretched based on the inelastic portion 140. Due to the configuration of the inelastic portion 140 provided between the upper elastic portion 131 and the lower elastic portion 133, the mechanical rigidity of the electrically conductive contact pin 100 may be ensured even if the length of the electrically conductive contact pin 100 is increased.

The inelastic portion 140 includes a hollow portion 145. The hollow portion 145 is formed by penetrating the inelastic portion 140 in the thickness direction (±z direction). A plurality of hollow portions 145 may be provided to be spaced apart from each other. The configuration of the hollow portion 145 allows the surface area of the inelastic portion 140 to be increased. Due to this, the heat generated in the inelastic portion 140 may be quickly dissipated, thereby suppressing the temperature rise of the inelastic portion 140. The shape of the hollow portion 145 is illustrated as a triangle, but is not limited thereto.

The electrically conductive contact pin 100 includes an outer wall portion 150 provided on the outside of the elastic portion 130 along the length direction of the electrically conductive contact pin 100 to guide the elastic portion 130 to be compressed and expanded in the length direction of the electrically conductive contact pin 100, and to prevent buckling by bending in the horizontal direction as the elastic portion 130 is compressed.

The outer wall portion 150 includes an upper outer wall portion 151 provided outside the upper elastic portion 131 and a lower outer wall portion 153 provided outside the lower elastic portion 133.

The first connection portion 110 descends vertically into the upper outer wall portion 151 to form an additional contact point between the first connection portion 110 and the upper outer wall portion 151. The second contact portion 120 rises vertically into the lower outer wall portion 153 and a second contact point performs a wiping operation. During the process of the electrically conductive contact pin 100 inspecting the inspection object, the electrically conductive contact pin 100 maintains a vertical state and the second contact portion 120 maintains contact pressure with the inspection object and performs a wiping operation on the inspection object while being tilted.

The upper outer wall portion 151 and the lower outer wall portion 153 are provided along the length direction of the electrically conductive contact pin 100, and the upper outer wall portion 151 and the lower outer wall portion 153 are integrally connected to the inelastic portion 140. In addition, the upper elastic portion 131 and the lower elastic portion 133 are integrally connected to the inelastic portion 140, and as a result, the electrically conductive contact pin 100 is composed of one body as a whole.

A locking portion 152 is provided on the outer wall of the upper outer wall portion 151 so that the electrically conductive contact pin 100 may be fastened to guide plates GP1 and GP2. That is, the upper outer wall portion 151 includes the locking portion 152 provided to protrude to prevent the electrically conductive contact pin 100 from being separated from the guide plates GP1 and GP2. The locking portion 152 may be configured to be caught by at least one of the guide plates GP1 and GP2. Preferably, the locking portion 152 may be configured to be caught on the upper guide plate GP1. In this case, the locking portion 152 includes an upper locking portion 152a caught on a first surface of the upper guide plate GP1, and a lower locking portion 152b caught on a second surface of the upper guide plate GP1. The electrically conductive contact pin 100 is not separated from the upper guide plate GP1 because the upper guide plate GP1 is caught between the upper locking portion 152a and the lower locking portion 152b. Meanwhile, the locking portion 152 may consist of an upper locking portion 152a caught on a first surface of the lower guide plate GP2, and a lower locking portion 152b caught on a second surface of the lower guide plate GP2.

The upper outer wall portion 151 includes a first upper outer wall portion 151a provided on one side of the upper elastic portion 131 and a second upper outer wall portion 151b provided on the other side of the upper elastic portion 131. The first upper outer wall portion 151a and the second upper outer wall portion 151b are close to each other at opposite ends thereof but are spaced apart from each other to form an upper opening 153a.

The lower outer wall portion 153 includes a first lower outer wall portion 153a provided on one side of the lower elastic portion 133 and a second lower outer wall portion 153b provided on the other side of the lower elastic portion 133. The first lower outer wall portion 153a and the second lower outer wall portion 153b are close to each other at opposite ends thereof but are spaced apart from each other to form a lower opening 153b.

The upper opening 153a and the lower opening 153b function to prevent the first and second connection portions 110 and 120 from excessively protruding out of the upper outer wall portion 151 and lower outer wall portion 153, respectively, by the restoring force of the upper elastic portion 131 and the lower elastic portion 133.

The first upper outer wall portion 151a has a first door portion 154a extending toward the upper opening 153a, and the second upper outer wall portion 151b has a second door portion 154b extending toward the upper opening 153a. The space where the first door portion 154a and the second door portion 154b face each other and are spaced apart becomes the upper opening 153a. The opening width of the upper opening 153a is smaller than the left-right length of the straight portion 130a of the upper elastic portion 131.

The first connection portion 110 is connected to the straight portion 130a of the upper elastic portion 131 and is provided in a rod shape that is formed long in the length direction of the electrically conductive contact pin 100. The first connection portion 110 may pass through the upper opening 153a formed by the first upper outer wall portion 151a and the second upper outer wall portion 151b in the vertical direction. In addition, as the left-right length of the straight portion 130a of the upper elastic portion 131 is provided to be larger than the width of the upper opening 153a, the straight portion 130a of the upper elastic portion 131 does not pass through the upper opening 153a. Due to this, the upward stroke of the first connection portion 110 is limited.

The upper outer wall portion 151 and lower outer wall portion 153 are close to each other at opposite ends thereof but are spaced apart from each other to form an upper opening 153a through which the first connection portion 110 may pass in the vertical direction. When the first connection portion 110 descends vertically inside the upper outer wall portion 151, the opening width of the upper opening 153a decreases and the first connection portion 110 contacts the upper outer wall portion 151 to form an additional contact point.

The first upper outer wall portion 151a has a first extension portion 155a extending into the internal space thereof, and the second upper outer wall portion 151b has a second extension portion 155b extending into the internal space thereof.

To be specific, the first extension portion 155a is connected to the first door portion 154a. The first extension portion 155a has one end connected to the first door portion 154a and the other end extends into the internal space of the upper outer wall portion 151 to form a free end. The second extension portion 155b is connected to the second door portion 154b. The second extension portion 155b has one end connected to the second door portion 154b and the other end extends into the internal space of the upper outer wall portion 151 to form a free end.

The first connection portion 110 is provided with a first protruding piece 110a extending in the direction of the first extension portion 155a and a second protruding piece 110b extending in the direction of the second extension portion 155b. When the first connection portion 110 is lowered by pressing force, the first protruding piece 110a and the second protruding piece 110b may contact the first extension portion 155a and the second extension portion 155b, respectively.

When the first connection portion 110 is lowered, the first protruding piece 110a and the second protruding piece 110b may respectively contact the first extension portion 155a and the second extension portion 155b to create an additional contact point.

As the first extension portion 155a and the second extension portion 155b are formed inclined, when the first connection portion 110 descends vertically, the first protruding piece 110a and the second protruding piece 110b respectively press the first extension portion 155a and the second extension portion 155b, and the separation space between the first door portion 154a and the second door portion 154b is reduced. In other words, as the first connection portion 110 descends, the first door portion 154a and the second door portion 154b are deformed to come closer to each other, thereby reducing the opening width of the upper opening 153a. In this way, when the first connection portion 110 descends vertically inside the upper outer wall portion 151, the opening width of the upper opening 153a decreases, and the first connection portion 110 contacts the upper outer wall portion 151 to form an additional contact point.

As the first connection portion 110 descends, the first and second protruding pieces 110a and 110b and the first and second extension portions 155a and 155b primarily contact each other to form additional contact points, and due to the additional descending of the first connection portion 110, the first and second door portions 154a and 154b and the first connection portion 110 secondarily contact each other to form additional contact points. As the first connection portion 110 vertically descends in this way, an additional current path is formed between the first connection portion 110 and the upper outer wall portion 151. The additional current path is formed directly from the upper outer wall portion 151 to the first connection portion 110 without passing through the elastic portion 130. As the additional current path is formed, a more stable electrical connection is possible.

The opening width of the upper opening 153a decreases in proportion to the vertical downward distance of the first connection portion 110. In addition, when downward pressure is applied to the first connection portion 110 even after the first and second door portions 154a and 154b contact the first connection portion 110, the friction between the first and second door portions 154a and 154b and the first connection portion 110 increases further. The increased friction prevents excessive lowering of the first connection portion 110. Due to this, it is possible to prevent the elastic portion (more specifically, the upper elastic portion 131) from being excessively compressed and deformed.

The second connection portion 120 is connected to the lower elastic portion 133 at the top thereof, and an end of the second connection portion 120 passes through the lower opening 153b.

The second connection portion 120 includes: an inner body 121 connected to the lower elastic portion 133; an extension body 123 protruding outward from the lower outer wall portion 153; and a tip portion TP provided at the end of the extension body 123.

The second connection portion 120 repeatedly performs raising and lowering operations, and to prevent the inner body 121 from being separated from the outer wall portion 150, the left-right length of the lower surface of the inner body 121 is provided to be larger than the opening width of the lower opening 143b.

A hollow portion 122 is formed in the inner body 121. The hollow portion 122 is formed by penetrating the inner body 121 in the thickness direction (±z direction). Due to the configuration of the hollow portion 122, the inner body 121 may be compressed and deformed by pressing force, and as the inner body 121 is compressed and deformed, the wiping operation of the tip portion TP is performed more smoothly.

The extension body 123 extends from the inner body 121 and at least part of the extension body 123 passes through the lower opening 153b and is located outside the lower outer wall portion 153.

The tip portion TP is provided at an end of the extension body 123. The tip portion TP has smaller dimensions than the thickness direction dimensions of the extension body 123 and has a stacked number smaller than the number of metal layers constituting the extension body 123.

During the wiping operation of the tip portion TP, debris from the oxide layer formed on the surface of the inspection object is generated. The debris tends to grow continuously while being deposited on each other and clumping together. However, the debris is caught at the end of the extension body 123, which is the root of the tip portion TP, and is unable to grow any further and is naturally induced to fall. In this way, due to the configuration of the tip portion TP provided at the end of the extension body 123 with a thickness smaller than that of the extension body 123, the continued growth of oxide layer debris generated during the wiping process is prevented.

According to the manufacturing method of the electrically conductive contact pin 100, it is possible to set the actual width t of the plate constituting the elastic portion 130 to 10 μm or less, more preferably 5 μm. Since the elastic portion 130 may be formed by bending a plate with an actual width t of 5 μm, it becomes possible to reduce the overall width dimension W of the electrically conductive contact pin 100. As a result, narrow pitch response becomes possible. In addition, because the overall thickness dimension H may be configured within the range of 100 μm or more and 200 μm or less, it is possible to shorten the length of the elastic portion 130 while preventing damage to the elastic portion 130, and even if the length of the elastic portion 130 is shortened, it is possible to have an appropriate contact pressure due to the configuration of the plate. Furthermore, because the total thickness dimension H compared to the actual width t of the plate constituting the elastic portion 130 may be increased, resistance to the moment acting in the front-rear direction of the elastic portion 130 increases, and as a result, contact stability is improved.

The electrically conductive contact pins 100 and 200 according to the preferred embodiment of the present disclosure described above are provided in the inspection devices 10 and 20 and are used to transmit electrical signals by electrically and physically contacting the inspection object. The inspection devices 10 and 20 include the electrically conductive contact pins 100 and 200 inserted into the guide hole of at least one of the guide plates GP1 and GP2 and installed on the guide plates GP1 and GP2. The inspection devices 10 and 20 may be testing equipment used in a semiconductor manufacturing process, and for example, the inspection device may be a probe card or a test socket. The electrically conductive contact pins 100 and 200 may be electrically conductive contact pins provided on a probe card to inspect a semiconductor chip, and may be socket pins provided in a test socket for inspecting packaged semiconductor packages to inspect a semiconductor package. The inspection devices 10 and 20 in which the electrically conductive contact pins 100 and 200 according to the preferred embodiment of the present disclosure may be used are not limited thereto, and include any device for checking whether an inspection object is defective by applying electricity. The inspection object to be inspected by the inspection devices 10 and 20 may include a semiconductor device, a memory chip, a microprocessor chip, a logic chip, a light emitting device, or a combination thereof. For example, the inspection object includes a logic LSI (such as an ASIC, an FPGA, and an ASSP), a microprocessor (such as a CPU and a GPU), a memory (such as a DRAM, an HMC (hybrid memory cube), an MRAM (magnetic RAM), a PCM (phase-change Memory), an ReRAM (resistive RAM), an FeRAM (ferroelectric RAM), and a flash memory (NAND flash)), an LED (such as a micro flash of a mobile terminal, an in-vehicle light source, a projector light source, an LCD backlight, and general illuminations), a power device, an analog IC (such as a DC-DC converter and an insulated gate bipolar transistor (IGBT)), an MEMS (such as an acceleration sensor, a pressure sensor, an oscillator, and a gyro sensor), a wireless device (such as a GPS, an FM, an NFC, an RFEM, an MMIC, and a WLAN), a discrete device, a BSI, a CIS, a camera module, a CMOS, a passive device, a GAW filter, an RF filter, an RF IPD, an APE, and a BB.

As described above, although the present disclosure has been described with reference to the preferred embodiments, those skilled in the art may carry out various modifications or changes to the present disclosure without departing from the spirit and scope of the present disclosure as set forth in the patent claims below.

### DESCRIPTION OF REFERENCE NUMERALS

10, 20: inspection device
100, 200: electrically conductive contact pin
BP: body portion
TP: tip portion
510: first region
520: second region
530: third region

1. An electrically conductive contact pin comprising:
a body portion composed of a plurality of metal layers stacked in a thickness direction; and
a tip portion provided on at least one of a front-end portion and a base-end portion of the body portion,
wherein the tip portion has dimensions smaller than dimensions of the body portion in the thickness direction, and a metal layer constituting the tip portion is formed continuously of a same material as some of the metal layers constituting the body portion.

2. The pin of claim 1, wherein the tip portion is composed of a plurality of metal layers stacked in the thickness direction, and has a stacked number smaller than that of the metal layers constituting the body portion.

3. The pin of claim 1, wherein lowermost and uppermost layers of the body portion are composed of a first metal layer, whereas a lowermost layer of the tip portion is composed of a second metal layer and an uppermost layer of the tip portion is composed of the first metal layer.

4. The pin of claim 1, wherein a fine trench is provided on a side of the body portion and a side of the tip portion.

5. The pin of claim 1, wherein a slit provided inside the body portion is comprised, and the body portion elastically deforms in a width direction.

6. The pin of claim 1, wherein the body portion comprises an elastic portion provided by bending a plate, and the elastic portion elastically deforms in a length direction.

7. An electrically conductive contact pin comprising:
a first region composed of a plurality of metal layers stacked in a thickness direction;
a second region having smaller dimensions than dimensions of the first region in the thickness direction, having a stacked number smaller than that of the metal layers constituting the first region, and comprising a metal layer formed continuously with some of the metal layers constituting the first region; and
a third region located between the first region and the second region and connecting metal layers of a same material of the first region and the second region.

8. The pin of claim 7, wherein the second region is a tip portion that contacts an object to be connected.

9. The pin of claim 7, wherein the metal layers comprise a first metal layer and a second metal layer,
wherein the first metal layer is formed of a metal selected from rhodium (Rd), platinum (Pt), iridium (Ir), palladium (Pd), nickel (Ni), manganese (Mn), tungsten (W), phosphorus (Ph) or alloys thereof, or palladium-cobalt (PdCo) alloy, palladium-nickel (PdNi) alloy, or nickel-phosphorus (NiPh) alloy, nickel-manganese (NiMn), nickel-cobalt (NiCo) or Nickel-tungsten (NiW) alloy, whereas the second metal layer is formed of a metal selected from copper (Cu), silver (Ag), gold (Au), or alloys thereof.

10. The pin of claim 9, wherein the first metal layer is provided at lowermost and uppermost layers of the first region, whereas the second metal layer is provided at lowermost layers of the second and third regions, and the first metal layer is provided at uppermost layers of the second and third regions.

11. The pin of claim 7, wherein a metal layer of the third region comprises:
a first connection portion connected to a metal layer of the first region;
a second connection portion connected to a metal layer of the second region; and
a middle portion provided between the first connection portion and the second connection portion.

12. The pin of claim 11, wherein one of metal layers constituting the third region is in contact with the plurality of metal layers of the first region.

13. The pin of claim 12, wherein the middle portion is composed of a second metal layer.

14. A method for manufacturing an electrically conductive contact pin, the method comprising:
forming a first internal space by removing a part of a mold;
forming a metal layer in a first height section of the first internal space;
removing a part of the mold and forming a second internal space in communication with the first internal space; and
forming a metal layer in a second height section of the first internal space and in the second internal space.

15. The method of claim 14, wherein in the forming a metal layer in a first height section of the first internal space, metal layers are alternately plated to form the metal layer.

16. The method of claim 14, wherein in the forming a metal layer in a second height section of the first internal space and in the second internal space, metal layers are alternately plated to form the metal layer.

17. The method of claim 14, wherein the mold is a mold made of an anodic oxide material.
